(19) United States
(12) Patent Application Publication
(10) Pub. No.: US 2026/0065995 A1
(43) Pub. Date: Mar. 5, 2026

(54) COMPUTING-IN-MEMORY CIRCUIT

(71) Applicant: MACRONIX International Co., Ltd., Hsinchu (TW)

(72) Inventors: Hang-Ting Lue, Hsinchu County (TW); Teng-Hao Yeh, Hsinchu County (TW); Wei-Chen Chen, Taoyuan City (TW); Chun-Hsiung Hung, Hsin-Chu (TW); Hsin-Yi HO, Hsinchu City (TW)

(73) Assignee: MACRONIX International Co., Ltd., Hsinchu (TW)

(21) Appl. No.: 18/815,844

(22) Filed: Aug. 27, 2024

(51) Int. Cl. G11C 16/10; G11C 16/08; G11C 16/24

(52) U.S. Cl. CPC G11C 16/102; G11C 16/08; G11C 16/24

(57) ABSTRACT

A computing-in-memory circuit including latches and NOR gates is provided. Each latch has a word line, a bit line, a complementary bit line, and first and second output ends. The bit line is coupled to a local bit line of one memory string in a memory array. The complementary bit line is coupled to a local complementary bit line of the memory string. The memory string includes storage units, each having a memory cell pair. The second output end provides a weight signal, sensed by the latch, from the memory cell. Each NOR gate has a first input end coupled to the second output end of the latch, a second input end receiving an external input signal, and an output end outputting a product of the weight and input signals.

### BACKGROUND

### Technical Field

The disclosure relates to a computing-in-memory circuit.

### Description of Related Art

Recently, the development of artificial intelligence (AI) has been thriving. Computing related to AI requires substantial resources and energy. To speed up AI-related computing, people are attracted to the technology directly computing in memory, known as the computing-in-memory (CIM) technology, instead of reading data from memory and processing the data with ALU (arithmetic logic unit) and other circuits.

However, there is still room for improvement in computing in 3D flash memory. Therefore, the challenge is how to further improve the computing speed in 3D flash memory and reduce energy consumption.

### SUMMARY

Based on the above description, a computing in memory circuit is provided according to an embodiment of the disclosure. The computing in memory circuit includes a plurality of latches and a plurality of NOR gates. Each of the plurality of latches has a word line, a bit line, a complementary bit line, a first output end, and a second output end. The bit line of each latch is coupled to a local bit line of a corresponding memory string among a plurality of memory strings in a memory array, and the complementary bit line of each latch is coupled to a local complementary bit line of the corresponding memory string in the memory array. The corresponding memory string comprises a plurality of storage units. Each of the storage units includes a memory cell pair. The second output end provides a weight signal sensed by the latch from the memory cell pair. In addition, each of the plurality of NOR gates has a first input end, a second input end, and an output end. The first input end of each NOR gate is coupled to the second output end of a corresponding latch among the plurality of latches, the second input end of each NOR gate receives an external input signal, and the output end of each NOR gate outputs a product of the weight signal and the input signal.

According to another embodiment of the disclosure, a computing in memory circuit is provided. The computing in memory circuit includes a latch and a first logic circuit. The latch has a word line, a bit line, a complementary bit line, a first output end, and a second output end. The first logic circuit has a first input end, a second input end, and an output end. The output end is coupled to the word line of the latch, the first input end receives a control signal, and the second input end is coupled to a power supply voltage of the latch. The complementary bit line of the latch is coupled to a reference voltage. The power supply voltage is ramped up from a low level to a high level during an operation of the latch.

According to another embodiment of the disclosure, a computing in memory circuit is provided. The computing-in-memory circuit includes a plurality of latches, a plurality of first logic circuits, a plurality of second logic circuits. Each of the plurality of latches has a word line, a bit line, a complementary bit line, a first output end, and a second output end. The bit line of each of the plurality of latches is coupled to a local bit line of a corresponding memory string among a plurality of memory strings in a memory array. The corresponding memory string includes a plurality of storage units. Each of the plurality of storage units consists of a single memory cell. The second output end of each of the plurality of latches provides a weight signal sensed by the latch from the memory cell. The complementary bit line of the latch is coupled to a reference voltage. In addition, each of the plurality of first logic circuits has a first input end, a second input end, and an output end. The output end of each of the plurality of first logic circuits is coupled to the word line of a corresponding latch among the plurality of latches, the first input end of each of the plurality of first logic circuits receives a control signal, and the second input end of each of the plurality of first logic circuits is coupled to a power supply voltage of the corresponding latch among the plurality of latches. In addition, each of the plurality of second logic circuits has a first input end, a second input end, and an output end. The first input end of each of the plurality of second logic circuits is coupled to the second output end of the corresponding latch among the plurality of latches, the second input end of each of the plurality of second logic circuits receives an external input signal, and the output end of each of the plurality of second logic circuits outputs a product of the weight signal and the input signal.

### BRIEF DESCRIPTION OF THE DRAWINGS

FIG. 1 shows a structural schematic diagram of a 3D AND-type NOR flash memory device according to an embodiment of the disclosure.

FIG. 2 is a schematic diagram of a digital computing-in-memory circuit according to an embodiment of the disclosure.

FIG. 3 shows an example of the latch shown in FIG. 1.

FIG. 4 is a method of waking up a latch according to an embodiment of the disclosure.

FIG. 5 is a method of computing in memory according to an embodiment of the disclosure.

FIG. 6 is a variation of the latch array in FIG. 1.

FIG. 7A is a schematic diagram showing a simulated configuration according to an embodiment of the disclosure. FIG. 7B shows a waveform schematic diagram of waking up a latch through a memory array. FIG. 7C is a diagram showing various bias voltages of the aforementioned simulation.

FIG. 8A shows a waveform diagram of the operation and simulation results of waking up a latch through power decoding according to an embodiment of the disclosure. FIG. 8B shows a waveform diagram of waking up a latch through a memory array. FIG. 8C shows various bias voltages of the aforementioned simulation.

FIGS. 9A to 9C show diagrams of the simulation results regarding the proper functioning of the latch of the disclosure despite a delay time between a word line of the latch and a power supply voltage of the latch.

FIGS. 10A to 10C show diagrams of the simulation results of an energy consumption assessment according to an embodiment of the disclosure.

FIGS. 11A and 11B are diagrams showing the simulation results of several energy cost reduction methods according to an embodiment of the disclosure.

FIGS. 12A and 12B are schematic diagrams showing an entire 3D memory device having a digital computing in memory function according to an embodiment of the disclosure.

FIG. 13 is a schematic diagram showing a digital computing-in-memory circuit according to another embodiment of the disclosure.

FIG. 14 illustrates an example of the logic circuit shown in FIG. 13.

FIG. 15 illustrates a timing diagram of the operation for the power decode of the logic circuit in FIG. 13.

FIG. 16 is a schematic diagram showing a variation of the latch according to another embodiment of the disclosure.

FIGS. 17A and 17B show 3D memory devices according to other variations of an embodiment of the disclosure.

### DESCRIPTION OF THE EMBODIMENTS

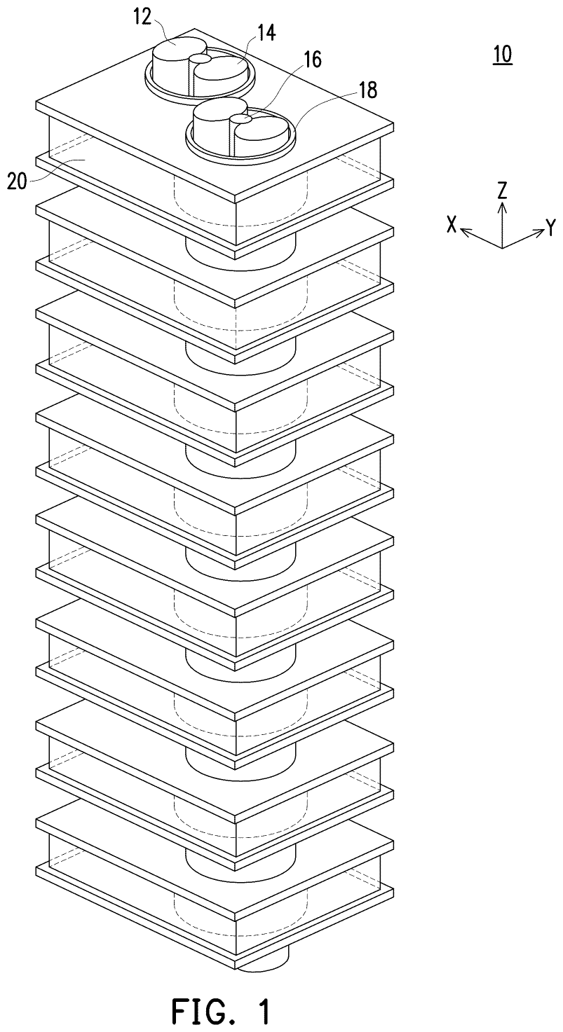

FIG. 1 shows a structural schematic diagram of a 3D AND-type NOR flash memory device according to an embodiment of the disclosure. The 3D AND-type NOR flash memory device may include a stacked structure 10 shown in FIG. 1. The stacked structure 10, for example, extends in a vertical direction (a direction Z) with multiple parallel gate layers 20. Each gate layer 20 is separated and isolated by dielectric materials (not shown) from another adjacent gate layer 20. The gate layer 20 may be further coupled to a conductive layer serving as a word line (not shown).

The stacked structure 10 includes a hollow channel pillar 18 extending in the vertical direction Z. An external surface of the hollow channel pillar 18 is surrounded by a charge storage structure (not shown). The charge storage structure is between the channel pillar and each of parallel gate layers 20. The charge storage structure may include multiple layers that can include a tunneling layer, a charge trapping layer, and a blocking layer. The tunneling layer can include a silicon oxide, or a silicon oxide/silicon nitride combination (e.g. oxide/nitride/oxide). The charge trapping layer can include silicon nitride or other materials capable of trapping or storing charges. The blocking layer can include silicon oxide, aluminum oxide, high-K dielectric material, and/or combinations of such materials. Two conductive pillars 12 and 14, which extend in the vertical direction Z and may serve as a source and a drain of a memory cell, are formed in the hollow channel pillar 18 and in contact with the hollow channel pillar 18. The two conductive pillars 12 and 14 have an insulating structure 16 extending in the vertical direction Z to separate the two conductive pillars 12 and 14.

In at least one embodiment of program operation method, a voltage is applied to the conductive pillar (drain side) and the conductive pillar (source side), since the conductive pillar (drain side) and the conductive pillar (source side) are connected to the channel pillar 18, electrons or charges may be transferred along the channel pillar 16 and stored in the charge storage structure intersecting with a specific selected gate layer 20 (word line). Accordingly, the program operation may be performed on a specific memory cell.

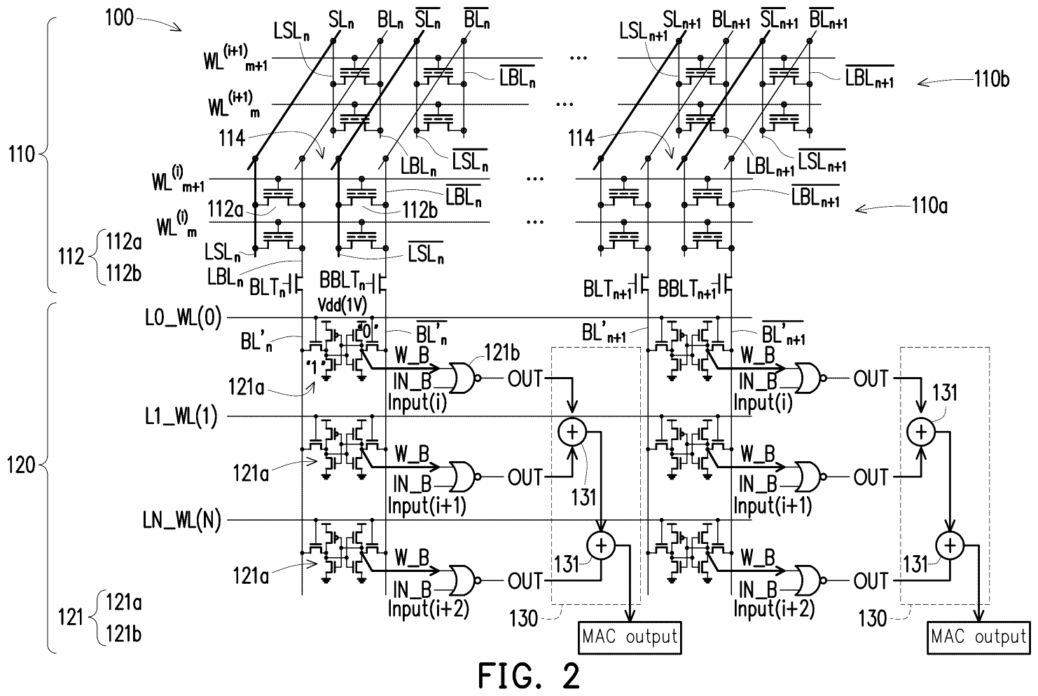

FIG. 2 is a schematic diagram of a digital computing-in-memory (CIM) circuit according to an embodiment of the disclosure. As shown in FIG. 2, a digital CIM circuit 100 includes a latch array 120, and multiple adder trees 130. In some cases, a memory device may be considered apart of the digital CIM circuit 100. Here, the memory device comprises, for example, a memory array 110. In an example, the memory array 110 is a 3D AND-type NOR flash memory array. Here, FIG. 2 only shows the part of the memory array comprising memory cells. Circuits related to other parts of the memory device (e.g., column decoders, row decoders, and other peripheral circuits) are omitted herein. A person skilled in the art may design other peripheral circuits according to the requirements for the actual functioning of the memory device.

In this embodiment, the memory array 110 is a 3D structure formed through the arrangement of multiple memory cells. The memory array 110 includes, for example, multiple stacked structures 10 as shown in FIG. 1, with FIG. 2 showing an i-th stacked structure 110a and an (i+1)-th stacked structure 110b as illustrative examples. In addition, each of the stacked structures 110a and 110b further includes multiple word lines (e.g., word lines WLₘ and WLₘ₊₁). In addition, each word line (e.g., the word line WLₘ₊₁) of each of the stacked structures 110a and 110b includes multiple memory cell pairs 112 (e.g., 112a, 112b). FIG. 2 shows nth and (n+1)-th memory cell pairs as illustrative examples. In addition, each of the stacked structures 110a and 110b may include multiple memory strings 114. The memory string 114 is formed by multiple stacked memory cell pairs. Each of the memory cell pairs 112 (e.g., 112a, 112b) of the memory string 114 is coupled to the same word line (e.g., WL⁽ⁱ⁾ₘ₊₁). Here, each of the memory cell pairs 112 functions as a storage unit.

Taking an (m+1)-th word line WL⁽ⁱ⁾ₘ₊₁ of the i-th stacked structure 110a as an example, the memory cell pair 112 includes a low threshold voltage memory cell 112a and a high threshold voltage memory cell 112b. Both the low threshold voltage memory cell 112a and the high threshold voltage memory cell 112b are flash memory cells. Both gates of the low threshold voltage memory cell 112a and the high threshold voltage memory cell 112b are coupled to the word line WL⁽ⁱ⁾ₘ₊₁. A source of the low threshold voltage memory cell 112a is coupled to a local source line LSLₙ, and a drain of the low threshold voltage memory cell 112a is coupled to a local bit line LBLₙ. Similarly, a source of the high threshold voltage memory cell 112b is coupled to a local complementary source line L̅S̅L̅ₙ̅, and a drain of the high threshold voltage memory cell 112b is coupled to a local complementary bit line L̅B̅L̅ₙ̅.

Each stacked structure includes multiple stacked memory cell pairs 112. For example, the i-th stacked structure 110a includes multiple local source lines, multiple local bit lines, multiple local complementary source lines, and multiple local complementary bit lines. However, FIG. 2 only shows local source lines LSLₙ and LSLₙ₊₁, local bit lines LBLₙ and LBLₙ₊₁, local complementary source lines L̅S̅L̅ₙ̅ and L̅S̅L̅ₙ̅₊̅₁̅, and local complementary bit lines L̅B̅L̅ₙ̅ and L̅B̅L̅ₙ̅₊̅₁̅ as examples. Taking the n-th memory cell pair of the i-th stacked structure 110a as an example, the local source line LSLₙ extends vertically and is connected to a first end (a source/drain end) of each low threshold voltage memory cell 112a respectively. The local bit line LBLₙ extends vertically and is connected to a second end (a source/drain end) of each low threshold voltage memory cell 112a respectively.

Similarly, the local complementary source line L̅S̅L̅ₙ̅ extends vertically and is connected to a first end (a source/drain end) of each high threshold voltage memory cell 112b respectively. The local complementary bit line L̅B̅L̅ₙ̅ extends vertically and is connected to the second end (the source/drain end) of each low threshold voltage memory cell 112a respectively.

Similarly, taking the (n+1)-th memory cell pair of the i-th stacked structure 110a as an example, the local source line LSLₙ₊₁ extends vertically and is connected to the first end (the source/drain end) of each low threshold voltage memory cell 112a respectively. The local bit line LBLₙ₊₁ extends vertically and is connected to the second end (the source/drain end) of each low threshold voltage memory cell 112a respectively. Similarly, the local complementary source line L̅S̅L̅ₙ̅₊̅₁̅ extends vertically and is connected to a first end (a source/drain end) of each high threshold voltage memory cell 112b respectively. The local complementary bit line L̅B̅L̅ₙ̅₊̅₁̅ extends vertically and is connected to the second end (the source/drain end) of each low threshold voltage memory cell 112a respectively.

The local source lines LSLₙ and LSLₙ₊₁ of each of the stacked structures 110a and 110b are further connected to the source line SLₙ and a source line SLₙ₊₁ respectively. The local bit lines LBLₙ and LBLₙ₊₁ of each of the stacked structures 110a and 110b are further connected to the bit line BLₙ and a bit line BLₙ₊₁ respectively. The local complementary source lines L̅S̅L̅ₙ̅ and L̅S̅L̅ₙ̅₊̅₁̅ of each of the stacked structures 110a and 110b are further connected to the complementary source line SLₙ and a complementary source line S̅L̅ₙ̅₊̅₁̅ respectively. The local complementary bit lines L̅B̅L̅ₙ̅ and L̅B̅L̅ₙ̅₊̅₁̅ of each of the stacked structures 110a and 110b are further connected to the complementary bit line B̅L̅ₙ̅ and a complementary bit line B̅L̅ₙ̅₊̅₁̅ respectively.

The local bit line LBLₙ and the local complementary bit line L̅B̅L̅ₙ̅ are further coupled to bit line selection transistors BLTₙ and BBLTₙ respectively, while the local bit line LBLₙ₊₁ and the local complementary bit line L̅B̅L̅ₙ̅₊̅₁̅ are further coupled to bit line selection transistors BLTₙ₊₁ and BBLTₙ₊₁ respectively. Through the bit line selection transistors BLTₙ, BBLTₙ, BLTₙ₊₁, and BBLTₙ₊₁, it is possible to select which local bit line is to be sensed.

As shown in FIG. 2, the latch array 120 is further disposed for each stacked structure. FIG. 2 shows the exemplified latch array 120 for the stacked structure 110a. As in the example shown in FIG. 2, the latch array 120 is an array having a number of N+1 word lines (i.e., L0_WL(0) to LN_WL(N)). Each of the word lines includes (n+1) latches 121a. The number of (n+1) latches 121a is basically the same as the number of memory cell pairs 112 on each word line of the memory array 110.

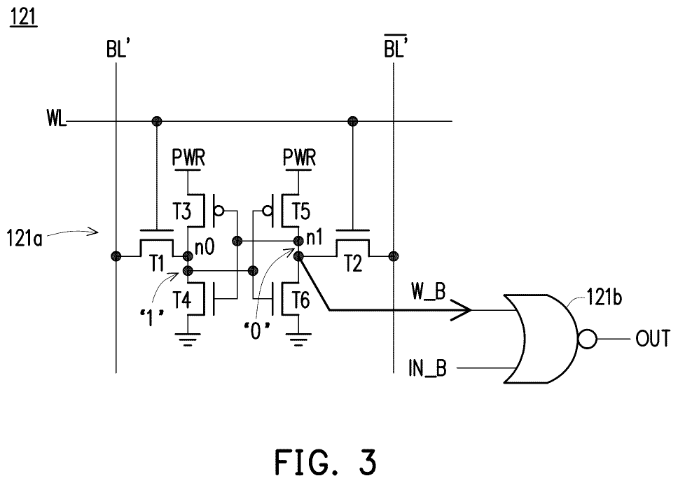

FIG. 3 shows an example of a latch circuit 121 shown in FIG. 2. As shown in FIG. 3, the latch circuit 121 includes the latch 121a and a NOR gate 121b. Here, as an example, the latch 121a may be a circuit including 6 transistors T1 to T6, making the latch 121a equivalent to an SRAM structure. The transistors T3 to T6 form two inverter circuits connected back to back.

In this configuration, the latch 121a may include a word line WL (i.e., one of the aforementioned word lines L0_WL(0)˜LN_WL(N)), a bit line BL′, and a complementary bit line B̅L̅′̅. The latch 121a may be selected by applying a suitable voltage to the word line WL, and data may be written into the latch 121a through the bit line BL′ and the complementary bit line B̅L̅′̅.

In this example, the gates of the transistors T1 and T2 (as pass gates) are coupled together and serve as the word line WL of the latch 121a. An end of the transistor T1 is coupled to the bit line BL′, and the other end of the transistor T1 is coupled to an end (a node n0) of the inverter circuit formed by the transistors T3 to T6. An end of the transistor T2 is coupled to the complementary bit line B̅L̅′̅, and the other end of the transistor T2 is coupled to the other end (a node n1) of the aforementioned inverter circuit. In this example, the node n0 is a logic “1”, and the node n1 is a logic “0”. In addition, the nodes n0 and n1 may be used as a first output end and a second output end of the latch 121a. The bit line BL′ and the complementary bit line B̅L̅′̅ may be deemed a first input end and a second input end of the latch 121a.

Specifically, each of the transistors T1 to T6 has a control end as well as a first end and a second end (two source/drain ends). As described in FIG. 3, the control end of the transistor T1 (a first transistor) is coupled to the word line WL. The first end of the transistor T1 is coupled to a bit line BL, and the second end of the transistor T1 is coupled to the node n0 (a first node). The control end of the transistor T2 (a second transistor) is coupled to the word line WL. The first end of the transistor T2 is coupled to the complementary bit line B̅L̅′̅, and the second end of the transistor T2 is coupled to the node n1 (a second node). The control end of the transistor T3 (a third transistor) is coupled to the node n1. The first end of the transistor T3 is coupled to a power supply voltage PWR, and the second end of the transistor T3 is coupled to the node n0. The control end of the transistor T4 (a fourth transistor) is coupled to the node n1. The first end of the transistor T4 is coupled to the node n0, and the second end of the transistor T4 is coupled to a ground. The control end of the transistor T5 (a fifth transistor) is coupled to the node n0. The first end of the transistor T5 is coupled to the power supply voltage PWR, and the second end of the transistor T5 is coupled to the node n1. The control end of the transistor T6 (a sixth transistor) is coupled to the node n0. The first end of the transistor T6 is coupled to the node n1, and the second end of the transistor T6 is coupled to the ground. The transistors T3 and T5 are P-type transistors (e.g., PMOS transistors). The transistors T1, T2, T4, and T6 are N-type transistors (e.g., NMOS transistors).

In this example, an input end of the NOR gate 121b receives a weight signal W_B from the node n1 (the second output end). The other input end of the NOR gate 121b receives an external input signal IN_B. An output provides an output signal OUT. The output signal OUT is equal to a product of the input signal IN_B and the weight signal W_B. In addition, the truth table of each NOR gate 121b is shown in Table 1 below.

TABLE 1

| W_B | IN_B | OUT |
|---|---|---|
| 0 | 0 | 1 |
| 0 | 1 | 0 |
| 1 | 0 | 0 |
| 1 | 1 | 0 |

Returning to FIG. 2, the i-th stacked structure 110a still serves as the illustrative example and the other stacked structures have the same architecture. For the nth memory cell pair 112, the local bit line LBLₙ in the memory array 110 is coupled to a bit line BL′ₙ of each latch 121a on word lines L0_WL(0) to LN_WL(N) in the latch array 120 through the bit line selection transistor BLTₙ. The local complementary bit line L̅B̅L̅ₙ̅ in the memory array 110 is coupled to a complementary bit line B̅L̅′̅ₙ̅ of each latch 121a on the word lines L0_WL(0) to LN_WL(N) in the latch array 120 through the bit line selection transistor BBLTₙ.

Similarly, for the (n+1)-th memory cell pair 112, the local bit line LBLₙ₊₁ in the memory array 110 is coupled to a bit line BL′ₙ₊₁ of each latch 121a on the word lines L0_WL(0) to LN_WL(N) in the latch array 120 through the bit line selection transistor BLTₙ₊₁. The local complementary bit line L̅B̅L̅ₙ̅₊̅₁̅ in the memory array 110 is coupled to a complementary bit line B̅L̅′̅ₙ̅₊̅₁̅ of each latch 121a on the word lines L0_WL(0) to LN_WL(N) in the latch array 120 through the bit line selection transistor BBLTₙ₊₁.

An output of each latch 121a, i.e., a weight value (the weight signal W_B) stored in the memory cell pair 112 in the memory array 110 is sensed and provided to a first input of the NOR gate 121b, and a second input of the NOR gate 121b receives the external input signal IN_B. The NOR gate 121b performs a logic operation on the received weight signal W_B and the input signal IN_B, which is equivalent to performing a multiplication operation on the weight signal W_B and the input signal IN_B, and then outputs the output signal OUT.

In addition, the number of the adder trees 130 is the same as the number of the latches 121a on each word line (e.g., L0_WL(0)) in the latch array 120, i.e., the same as the number of the memory cell pairs 112 on each word line in the memory array 110. Each adder tree 130 includes multiple adders 131. In this example, the number of the adders 131 is the number of word lines in the latch array 120 minus 1. Namely, the number of word lines in the latch array 120 is N+1, which makes the number of the adders 131 to be N.

Each adder tree 130 receives the output signal OUT of the NOR gate 121b corresponding to each latch 121a in each column of the latch array 120, performs an addition operation on the output signal OUT of each NOR gate 121b, and outputs a result of summation. For example, after adding the output signals OUT of a first NOR gate 121b and a second NOR gate 121b through a first adder 131, the output signal OUT of a third NOR gate 121b is further added to the sum of the output signals OUT of the first and second NOR gates 121b through a second adder 131. According to this method, the output signals OUT of all NOR gates 121b are summed and a multiply-and-accumulate (MAC) output is performed.

Here, each of the NOR gates 121b in the latch array 120 performs a multiplication operation on the weight value and the input signal, and each adder tree sums the output signals of the corresponding NOR gates 121b, thereby performing the computing in memory for obtaining a MAC value.

In the digital CIM circuit 100 in this embodiment, a memory cell pair 112 is used to wake up the latch 121a in the latch array 120. As described above, one side of the memory cell pair 112 is the low threshold voltage memory cell 112a, and the other side is the high threshold voltage memory cell 112b. For example, when the low threshold voltage memory cell 112a is selected for sensing, the level of the corresponding local bit line LBLₙ is increased while the level of the complementary local bit line L̅B̅L̅ₙ̅ corresponding to the high threshold voltage memory cell 112b is kept low.

Thus, according to the embodiment of the disclosure, the voltage difference between the local bit line LBLₙ and the local complementary bit line L̅B̅L̅ₙ̅ may wake up the latch 121a for sensing. That is, a voltage difference exists between the two ends of the inverter circuit (e.g., the two ends n0 and n1 in FIG. 3) of the latch 121a and the state of the latch 121a can be transient, thereby promptly transmitting the weight value stored in the memory cell pair 112 to the latch 121a.

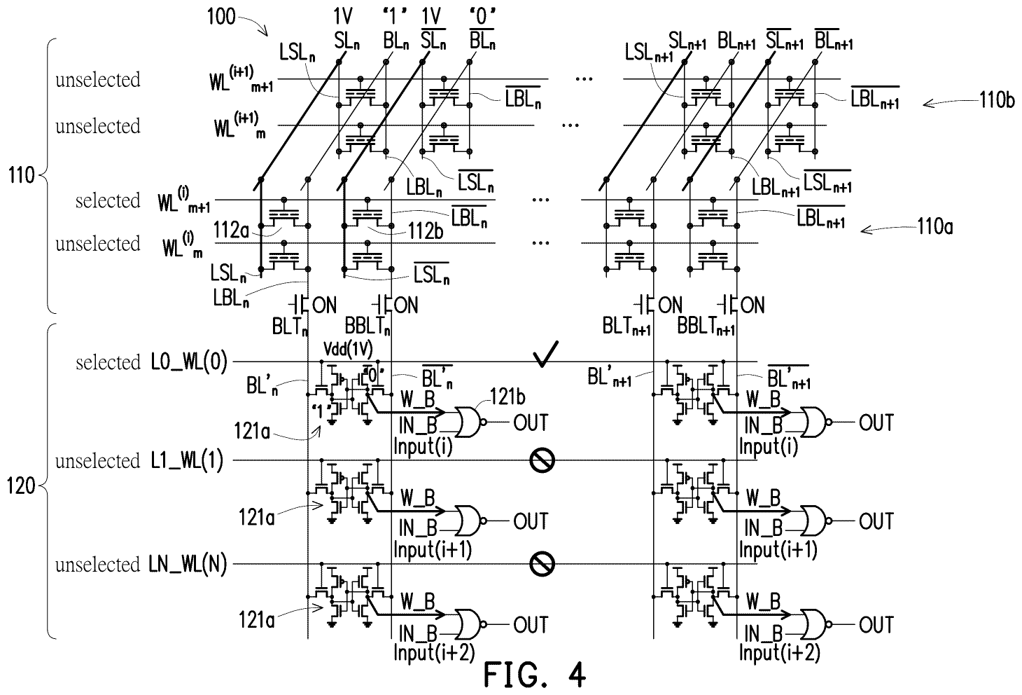

FIG. 4 is a method of waking up a latch according to an embodiment of the disclosure. Before dCIM is performed, each latch 121a in the latch array 120 first performs sensing on each memory cell pair 112 in the memory array 110, and the value read through sensing serves as the weight signal W_B (the weight value). As shown in FIG. 4, a word line is first selected from the memory array 110. For example, when the word line WL⁽ⁱ⁾ₘ₊₁ is selected, a voltage (e.g., 6.8V) is applied to the word line WL⁽ⁱ⁾ₘ₊₁ so as to make the state of the word line WL⁽ⁱ⁾ₘ₊₁ a selected state. For the other word lines, unselected voltages (e.g., 0V) are applied so as to make the state of the other word lines an unselected state. In addition, a voltage of 1V is applied to the source line SLₙ and the complementary source line S̅L̅ₙ̅. In addition, the voltage of 1V may be applied to the source line SLₙ₊₁ and the complementary source line S̅L̅ₙ̅₊̅₁̅ corresponding to other memory cell pairs 112 (such as the (n+1)-th pair, etc.) on the word line WL⁽ⁱ⁾ₘ₊₁.

At the same time, the gates of the bit line selection transistors BLTₙ and BBLTₙ connected to the local bit line LBLₙ and the local complementary bit line L̅B̅L̅ₙ̅ may also be turned on by applying proper voltages on the gates. The gates of the bit line selection transistors BLTₙ₊₁ and BBLTₙ₊₁ connected to the local bit line LBLₙ₊₁ and the local complementary bit line L̅B̅L̅ₙ̅₊̅₁̅ may also be turned on by applying proper voltages on the gates. In addition, for example, when the word line L0_WL(0) in the latch array 120 is selected for data transmission, the other word lines L0_WL(1) to L0_WL(N) are disabled in an unselected state.

At this time, under the bias voltage state of the memory cell pair 112, the low threshold voltage memory cell 112a is turned on and the high threshold voltage memory cell 112b is turned off, thereby forming a current path starting from the source line SLₙ and passing through the local source line LSLₙ, the low threshold voltage memory cell 112a, the local bit line LBLₙ, and the bit line selection transistor BLTₙ, further transmitting the data stored in the low threshold voltage memory cell 112a to the latch 121a. In addition, as the high threshold voltage memory cell 112b is not turned on, the current in the path of the local complementary bit line L̅B̅L̅ₙ̅ is much smaller.

As a result, there is a voltage difference between the bit line BL′ₙ and the complementary bitline B̅L̅′̅ₙ̅ of the latch 121a (or between the nodes n0 and n1). The voltage difference changes the state of the latch 121a. The data stored in the low threshold voltage memory cell 112a is further sensed and directly transmitted to the NOR gate 121b.

The above operations may continue until data is sensed by all the latches 121a in all the latch arrays 120. In addition, a different word line may be selected for the memory array 110 to sense a different memory cell pair 112 when, for example, deciding to sense data for the latch 121a on the word line L1_WL(1) in the latch array 120. By selecting a combination of different word lines in the memory array 110 and different word lines in the latch array 120, multiplication operations on different input signals and weight values may be performed.

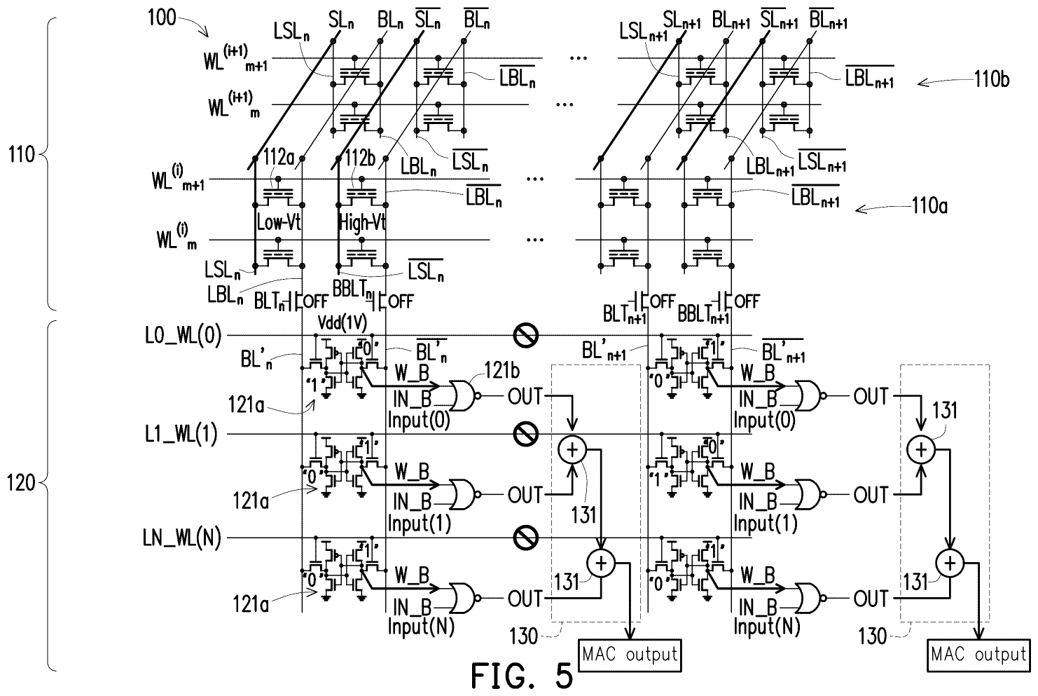

FIG. 5 is a method of computing in memory according to an embodiment of the disclosure. After the memory array 110 wakes up the latch array 120, i.e., after the latch array 120 reads the weight value stored in the required memory cell pair in the memory array 110, proper voltages are applied to the gates of the bit line selection transistors BLTₙ, BBLTₙ, BLTₙ₊₁, and BBLTₙ₊₁ in order to turn off the bit line selection transistors BLTₙ, BBLTₙ, BLTₙ₊₁, and BBLTₙ₊₁. At this time, the subsequent operation of the latch array 120 and the adder tree 130 is independent of the memory array 110.

In addition, an unselected voltage is applied to each of the word lines L0_WL(1) to LN_WL(N) in the latch array 120 to make theses word lines in an unselected state. As a result, the digital CIM circuit 100 starts performing the digital CIM. At this time, an input end of the NOR gate 121b connected to each latch 121a in the latch array 120 receives the weight signal W_B while the other input end receives the external input signal IN_B (i.e., input (0) to input (N)). At this time, each NOR gate 121b may perform a logic operation on the weight signal W_B and the input signal IN_B rapidly to obtain the output signal OUT which is the product of the weight signal W_B and the input signal IN_B.

Thereafter, the output signals of the NOR gates 121b in the same column in the latch array 120 are further transmitted to the adder tree 130. An addition operation is performed on each of the output signals OUT of the NOR gates 121b through the adders 131 of the adder tree 130 so as to output a MAC value.

According to the embodiment of the disclosure, the weight data stored in the memory array 110 may be reused for convolution operations simply by changing a MAC input (the input signal IN_B of the NOR gate 121b). In addition, according to the embodiment of the disclosure, all circuits performing digital CIM (the latch 121a, the NOR gate 121b, and each of the adders 131 of the adder tree 130) are configured by MOS transistors. This is not related to the memory array 110 because the bit line selection transistors BLTₙ, BBLTₙ, etc. in the memory array 110 are turned off during digital CIM. Therefore, the performance of digital CIM is only related to the layout, CMOS configuration, metal windings, and configuration of the adder trees. Therefore, once the latch 121a senses the required weight value, the multiplication and addition operations may be performed almost instantly and further output the MAC value.

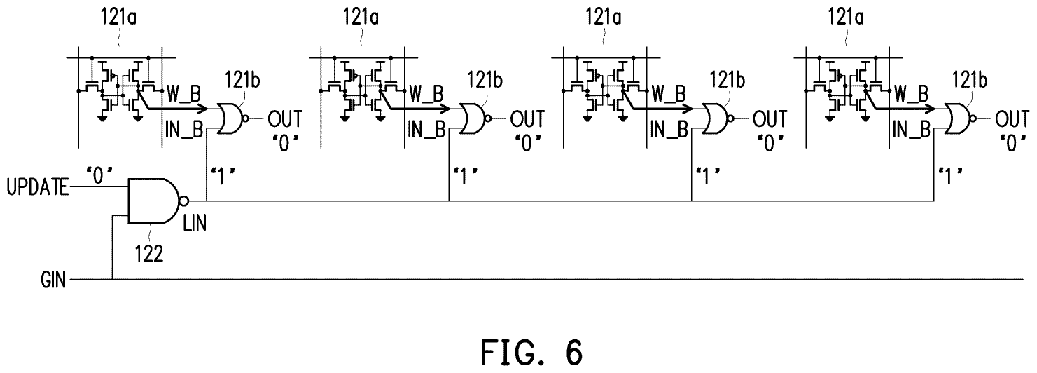

FIG. 6 is a variation of the latch array in FIG. 1. The NOR gate 121b may be operated at any time if there is any change in the weight signal W_B. Therefore, if the memory array 110 wakes up each of the latches 121a in the latch array 120, the levels of the nodes n0 and n1 of each of the latches 121a may change when the latch 121a senses data from the memory cell pair 112 in the memory array 110.

Once the state of nodes n0 and n1 changes, the NOR gate 121b will be inadvertently activated and start operating, further generating the output signal OUT. The output signal OUT further causes the operation of each adder tree 130. Therefore, when waking up the latches 121a in the latch array 120, it is preferable that each NOR gate 121b and adder tree 130 does not operate, otherwise misfunction might occur. Therefore, it is necessary to fix the output of the NOR gate 121b during the phase of waking up each of the latches 121a in the latch array 120, thereby eliminating improper operation of each adder tree 130 and reducing power consumption.

To achieve this objective, as shown in FIG. 6, a NAND gate 122 may be further provided for the disclosure to control the output of each NOR gate 121b. As an example, the NAND gate 122 has a first input end, a second input end, and an output end. The first input end receives an update signal UPDATE. The second input end receives a global input signal GIN, and the output end outputs a local input signal. Through the concept of shared input signals, during the phase of waking up each latch 121a, if the input signals IN_B of the NOR gate 121b are all set to the logic “1”, the output signal OUT of the NOR gate 121b becomes the logic “0”. In this manner, changes in the output signal OUT of the NOR gate 121b may be avoided during the phase of waking up each latch 121a, further avoiding the corresponding operation of the adder tree 130.

In this case, if dCIM is not performed during the phase of waking up each latch 121a, the update signal UPDATE input to the NAND gate 122 may be set to the logic “0”. As a result, the output end of the NAND gate 122 outputs the logic “1” regardless of the logic state of the global input signal GIN, enabling the output signal OUT of the NOR gate 121b to become the logic “0”. A truth table of the NAND gate 122 is listed in Table 2 below.

TABLE 2

| Global Input Signal | Update Signal | Local Input Signal |
|---|---|---|
| GIN | UPDATE | LIN |
| 0 | 0 | 1 |
| 1 | 0 | 1 |
| 0 | 1 | 1 |
| 1 | 1 | 0 |

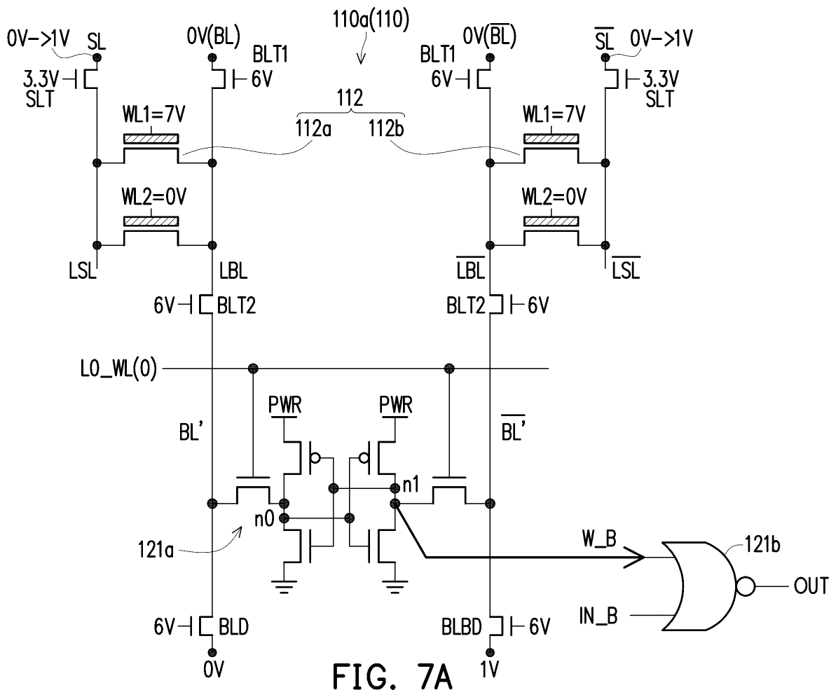

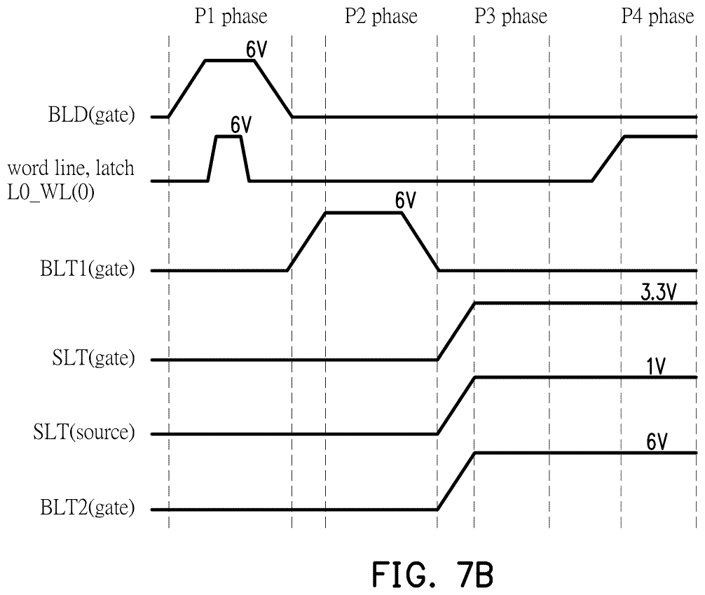

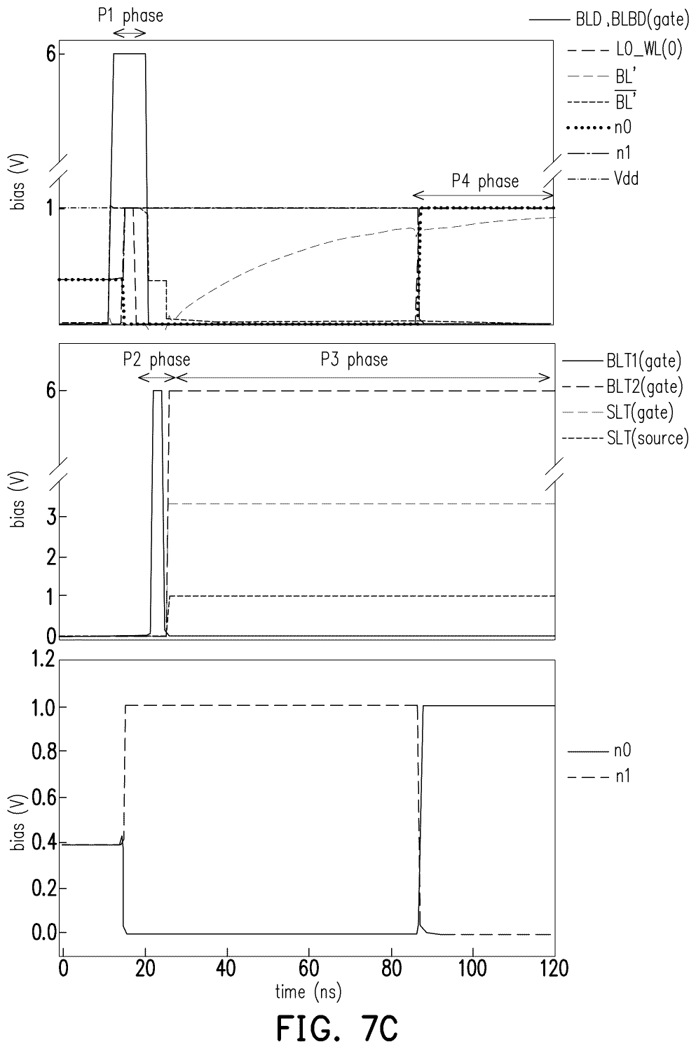

A description of some of the simulation results under the configuration of FIG. 2 is provided below to show that the above-mentioned configuration is implementable. FIG. 7A is a schematic diagram showing a simulation configuration according to an embodiment of the disclosure. FIG. 7A illustrates two word lines WL1 and WL2 in the stacked structure 110a in FIG. 2 as an example. As described above, each memory cell pair 112 includes the low threshold voltage memory cell 112a and the high threshold voltage memory cell 112b. In addition, FIG. 7A only shows an exemplified latch 121a coupled to a local bit line LBL and a complementary local bit line L̅B̅L̅.

In addition, the latch 121a further includes bit line drivers BLD and BLBD for driving the bit line BL′ and the complementary bit line B̅L̅′̅ respectively. In addition, the memory array 110 further includes source line selection transistors SLT (a source line selection transistor SLT on each of the left and right sides in FIG. 7A) coupled to the local source line LSL and the complementary local source line L̅S̅L̅. By applying voltages to the source line SL and the complementary source line S̅L̅ through the source line selection transistors SLT, the local source line LSL and the complementary local source line L̅S̅L̅ may be charged.

In this simulation, the word line WL1 is selected and the word line WL2 is unselected. Therefore, a voltage of 7V is applied to the word line WL1 to enable the word line WL1, and a voltage of 0V is applied to the word line WL2 (including other unselected word lines) to disable the word line WL2.

FIG. 7B shows a waveform schematic diagram of waking up a latch through a memory array. FIG. 7C is a diagram showing various bias voltages of the aforementioned simulation.

Here, the wake-up process generally includes four phases, i.e., a P1 phase, a P2 phase, a P3 phase, and a P4 phase. As shown in FIGS. 7A to 7C, during the P1 phase, the bit line BL′ and the complementary bit line B̅L̅′̅ of the latch 121a are driven by the bit line drivers BLD and BLBD respectively, and a voltage (e.g. 6 volts or 6V) is applied to the word line (e.g. L0_WL(0)) of the latch 121a to set the initial state of the latch 121a.

Next, during the P2 phase, the local bit line LBL and the complementary bit line L̅B̅L̅ are selected through a bit line selection transistor BLT1 (e.g., a voltage of 6V is applied to a gate of the bit line selection transistor BLT1, and voltages of 0V are applied to the bit line BL and the complementary bit line B̅L̅), and the bias voltages of the local bit line LBL and the complementary local bit line L̅B̅L̅ are set. Then, the bit line selection transistor BLT1 is turned off so that the state of the local bit line LBL and the complementary local bit line L̅B̅L̅ becomes a floating state.

Next, during the P3 phase, a voltage of 3.3V (volts) is applied to the gate of the source line selection transistor SLT to turn on the source line selection transistor SLT, and the voltage of the source of the source line selection transistor SLT increases from 0V to 1V as the voltage of the source line SL increases from 0V to 1V. At the same time, a voltage of 6V is applied to a gate of a bit line selection transistor BLT2 to turn on the bit line selection transistor BLT2. As a result, a current path starting from a source line SL and passing through a local source line LSL, the low threshold voltage memory cell 112a, the local bit line LBL, and the selection transistor BLT2 is formed. In addition, as mentioned in previous paragraphs for FIG. 4, the high threshold voltage memory cell 112b is not turned on. The current in the path of the local complementary bit line L̅B̅L̅ₙ̅ is much smaller than the local bit line LBLₙ.

Thereafter, during the P4 phase, a proper voltage is applied to the word line L0_WL(0) of the latch 121a to enable the word line L0_WL(0), thereby waking up the latch 121a. Through this operation, the state of the nodes n0 and n1 of the latch 121a may be changed, and the data stored in the memory cell pair 112 may be transmitted to the latch 121a, i.e., the weight data stored in the memory cell pair 112 may be written into the latch 121a.

In this simulation result, as can be seen from the uppermost and bottommost graphs in FIG. 7C, the state of the nodes n0 and n1 of the latch 121a (referring to FIG. 3) is correctly changed, i.e., the data from the memory cell pair 112 is correctly sensed. That is, the latch 121a is successfully woken up and functions properly. This indicates that the digital CIM circuit 100 shown in FIG. 2 is a feasible architecture.

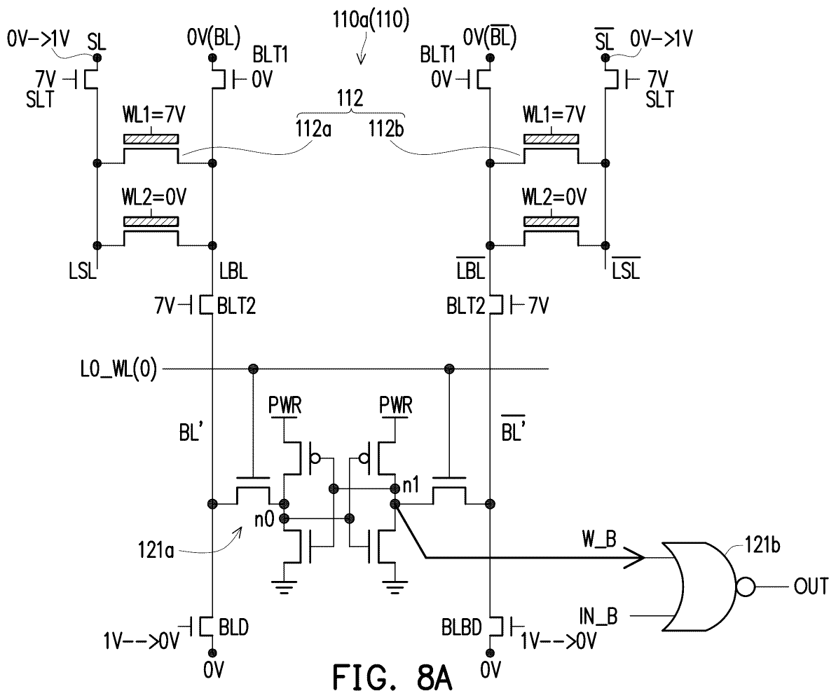

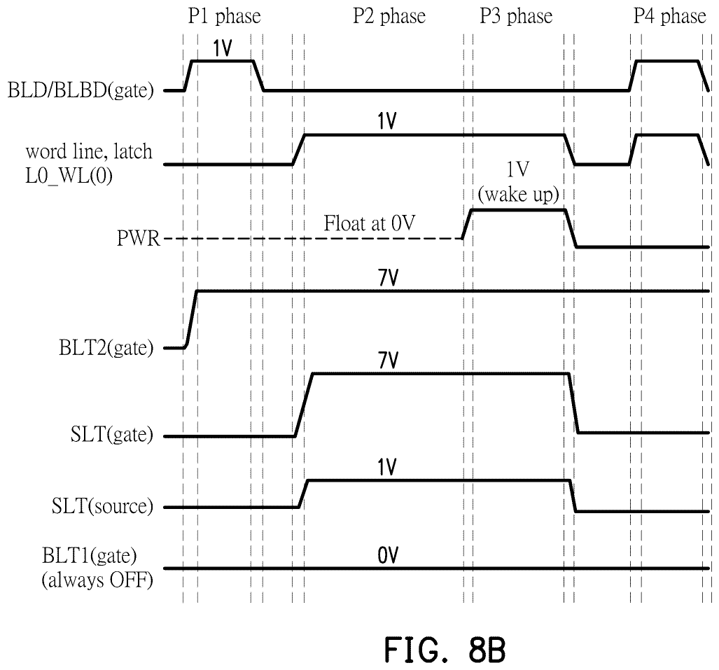

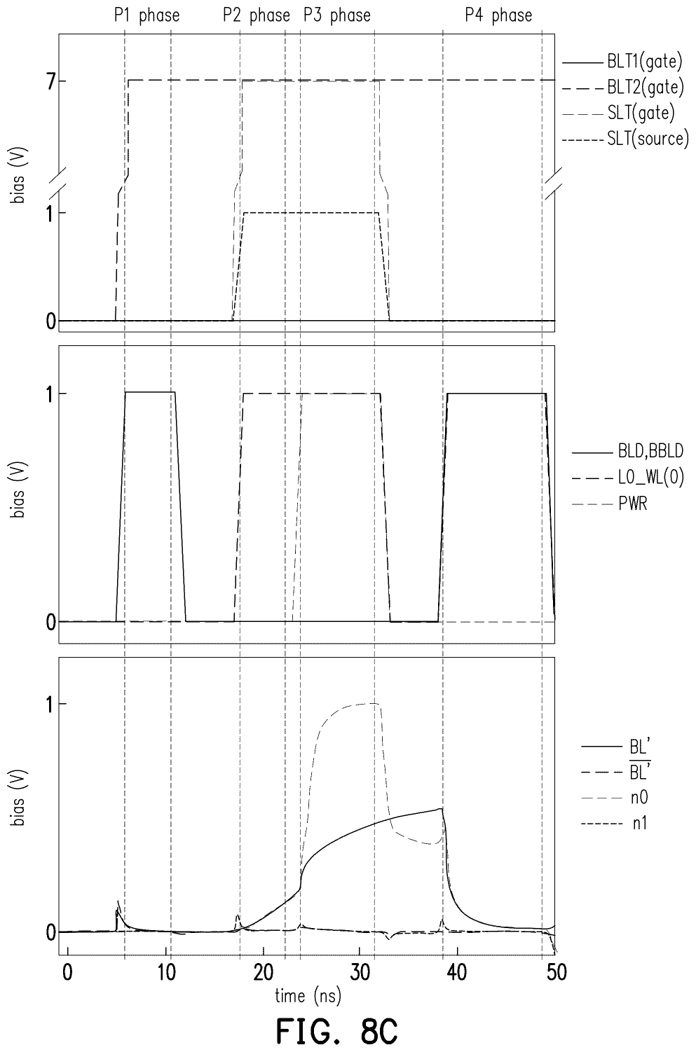

FIG. 8A is a schematic diagram showing a simulated configuration according to another embodiment of the disclosure. The exemplified circuit in FIG. 8A is basically the same as that in FIG. 7A, except that some of the bias voltages used in the simulation vary in response to the power decoding operation. Other than this difference, reference may be made to the description regarding FIG. 7A for the remaining parts. In the above description, the power supply voltage PWR for the latch 121a is continuously supplied (e.g., a voltage of 1V is continuously applied). Therefore, before the memory array 110 wakes up each latch 121a, the latch 121a has already stored a data. Thus, when writing a data into the latch 121a, a signal fighting issue is likely to be generated between the data and the existing data. Therefore, in this embodiment, a method of power decoding is adopted to wake up the latch 121a. That is, before the memory array 110 wakes up each latch 121a, the power supply voltage PWR is not applied, i.e., the latch 121a is left in the floating state. After the local bit line LBL and the complementary local bit line L̅B̅L̅ in the memory array 110 and the bias voltages of the bit line BL′ and the complementary bit line B̅L̅′̅ of the latch 121a are set, the power supply voltage PWR is then applied so as to wake up each latch 121a.

In addition, FIG. 8B shows a waveform schematic diagram of waking up a latch through a memory array according to another embodiment. FIG. 8C is a diagram showing various bias voltages of the aforementioned simulation. Here, the wake-up process generally includes four phases, i.e., a P1 phase, a P2 phase, a P3 phase, and a P4 phase. As shown in FIGS. 8A to 8C, during the P1 phase, the bit line BL′ and the complementary bit line B̅L̅′̅ of the latch 121a are pre-charged to 0V through the bit line drivers BLD and BLBD respectively, and then the bit line drivers BLD and BLBD are turned off and the bit line BL′ and the complementary bit line B̅L̅′̅ are in the floating state. At this time, a voltage of 7V is applied to the gates of the bit line selection transistors BLT2 (on both the left and right sides) to turn on the bit line selection transistors BLT2. During this phase P1, the power supply voltage PWR remains in a floating state (about 0V).

Next, during the P2 phase, a voltage of 7V is applied to the gates of the source line selection transistors SLT to turn on the source line selection transistors SLT (on both the left and right sides), and the voltage of the source of the source line selection transistors SLT increases from 0V to 1V as the voltage of the source line SL increases from 0V to 1V. At the same time, the bit line selection transistor BLT1 is always turned on. As a result, a current path starting from the source line SL and passing through the local source line LSL, the low threshold voltage memory cell 112a, the local bit line LBL, and the bit line selection transistor BLT2 is formed. During the P2 phase, the power supply voltage PWR remains in a floating state (about 0V). In addition, during the P2 phase, a voltage (e.g., 1 volt) started to be applied to the word line L0_WL(0) of the latch 121a so as to select the word line L0_WL(0).

Thereafter, during the P3 phase, the bias voltage of the local bit line LBL is set. At this time, the power supply voltage PWR (e.g., 1 volt) for the latch 121a is applied to wake up the latch 121a. Through this operation, the state of the nodes n0 and n1 of the latch 121a may be changed, and the data stored in the memory cell pair 112 may be transmitted to the latch 121a, i.e., the weight data stored in the memory cell pair 112 may be written into the latch 121a.

Finally, during the P4 phase, the bit line BL′ and the complementary bit line B̅L̅′̅ of the latch 121a are discharged. In addition, the bit line selection transistor BLT1 is always turned off throughout the entire phase.

In this simulation result, as can be seen from the graph at the bottom in FIG. 8C, the state of the nodes n0 and n1 of the latch 121a (referring to FIG. 3) is correctly changed, i.e., the data from the memory cell pair 112 is correctly sensed. That is, the latch 121a is successfully woken up and functions properly. This indicates that the digital CIM circuit 100 shown in FIG. 2 performing a power decoding with the power supply voltage PWR is feasible.

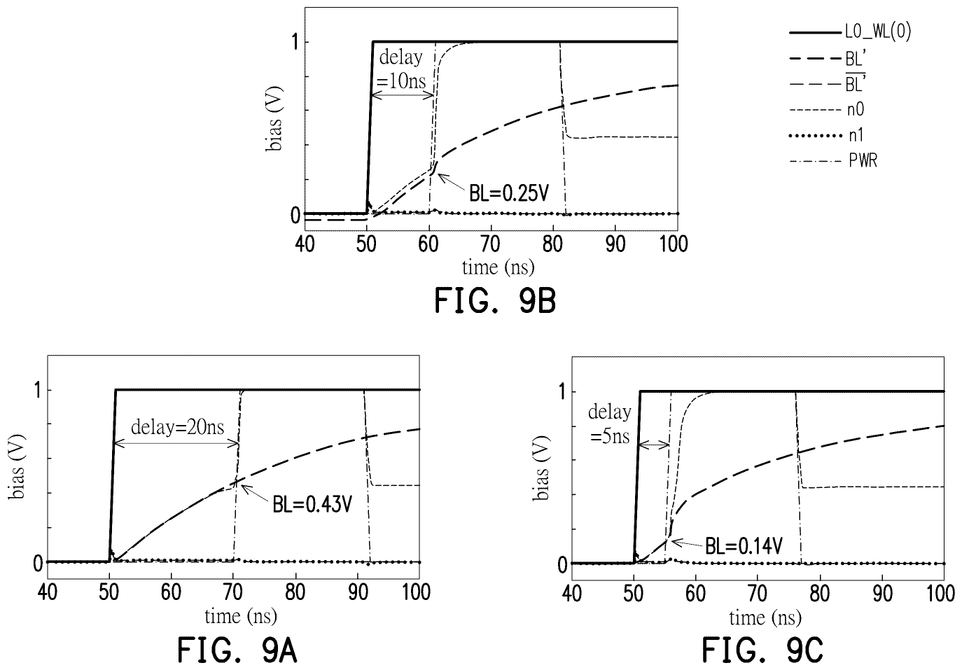

FIGS. 9A to 9C show diagrams of the simulation results regarding the proper functioning of the latch of the disclosure despite a delay time between a word line of the latch and a power supply voltage of the latch. FIGS. 9A to 9C confirm waveform diagrams of several delay times between the word line of the latch 121a (e.g., the word line L0_WL(0) in FIG. 2) and the power supply voltage PWR of the latch. With these delay times (e.g., 20 ns, 10 ns, and 5 ns), the set level of the bias voltage of the local bit line LBL may be changed. For example, when the delay times between the word line L0_WL(0) and the power supply voltage PWR of the latch are 20 ns, 10 ns, and 5 ns, the levels of the bias voltage of the local bit line LBL may be set to 0.43V, 0.25V, and 0.14V respectively. As can be seen in FIGS. 9A to 9C, even if the bias voltage of the local bit line LBL is only 0.14V, each latch 121a may still be properly woken up.

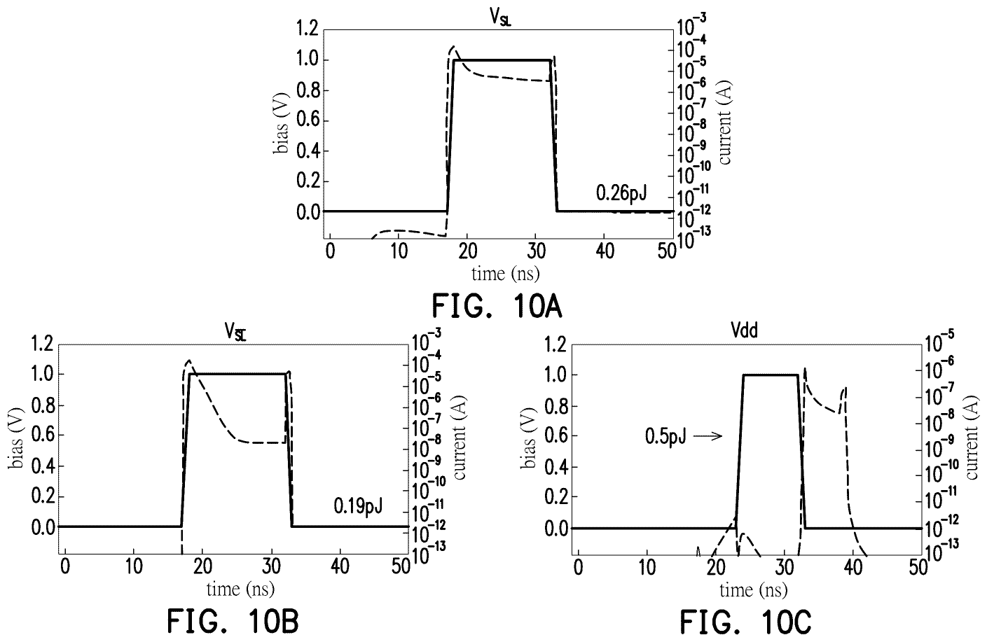

FIGS. 10A to 10C show diagrams of the simulation results of an energy consumption assessment according to an embodiment of the disclosure. Referring to FIG. 2 at the same time, as described above, when waking up the latch 121a through the memory array 110, a bias voltage of 1V is applied to the source line SLₙ and the complementary source line S̅L̅ₙ̅ in the memory array 110, and the power supply voltage PWR applied to the latch 121a is a voltage of about 1V. As a result, the latch 121a may be woken up, and the weight data stored in the memory cell pair 112 in the memory array 110 may be transmitted to the latch 121a.

Therefore, a voltage of 1V applied to the source line SLₙ and the complementary source line S̅L̅ₙ̅ as well as the power supply voltage PWR may be taken into consideration when performing the energy consumption assessment for waking up the latch 121a. Here, FIG. 10A shows a voltage V_{SL} of 1V applied to the source line SL and a current thereof. FIG. 10B shows a voltage V_{S̅L̅} of 1V applied to the complementary source line S̅L̅ and a current thereof. FIG. 10C shows the voltage PWR of 1V and a current thereof.

Accordingly, the total energy consumption (I*V*t, i.e., current*voltage*time) in an operating cycle is about 0.26 pJ+0.19 pJ=0.45 pJ. The energy consumption (0.5 aJ) of the power supply voltage PWR is very low, which is nearly negligible. In addition, the energy consumption of analog CIM (a method of utilizing a NOR memory array and a sense amplifier to sense the data of the array) is about 21 pJ. Therefore, the energy consumption of the digital CIM of the disclosure is relatively low.

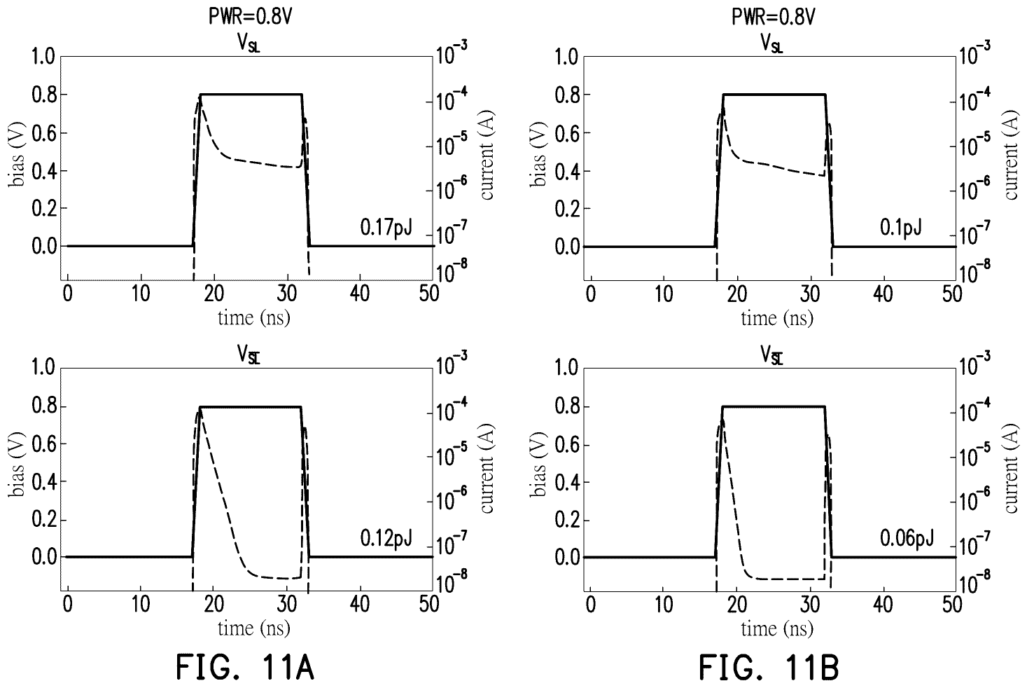

FIGS. 11A and 11B are diagrams showing the simulation results of several energy cost reduction methods according to an embodiment of the disclosure. In the simulation results in FIG. 11A, the power supply voltage PWR for the latch 121a decreases to 0.8V, but the capacitance of the bit line and the capacitance of the source line are set as the same as the capacitance in FIGS. 10A and 10B (e.g., 200 fF). At this time, the upper part of FIG. 11A shows that the source line SL may provide a voltage of only about 0.8V to charge the local bit line LBL with an energy consumption of 0.17 pJ. The lower part of FIG. 11A also shows that a voltage applied to the complementary source line S̅L̅ is about 0.8 V, with an energy consumption of 0.12 pJ. Since the energy consumption of the power supply voltage PWR of the latch 121a is still negligible, the total energy consumption is about 0.29 pJ.

In addition, in the simulation results in FIG. 11B, the power supply voltage PWR for the latch 121a decreases to 0.8V, but the capacitance of the bit line and the capacitance of the source line are set as half of the capacitance in FIGS. 10A and 10B (e.g., 100 fF). At this time, the upper part of FIG. 11B shows that the source line SL may provide a voltage of only about 0.8V to charge the local bit line LBL with an energy consumption of 0.1 pJ. The lower part of FIG. 11A also shows that a voltage applied to the complementary source line S̅L̅ is about 0.8 V, with an energy consumption of 0.06 pJ. Since the energy consumption of the power supply voltage PWR of the latch 121a is still negligible, the total energy consumption is about 0.16 pJ.

Therefore, as can be seen in the above simulation results, the energy consumption per bit may be effectively reduced by properly lowering the power supply voltage PWR of the latch 121a. Moreover, by reducing the capacitance of the bit line and the capacitance of the source line of the memory array 110 through design, the energy consumption per bit may also be reduced more effectively.

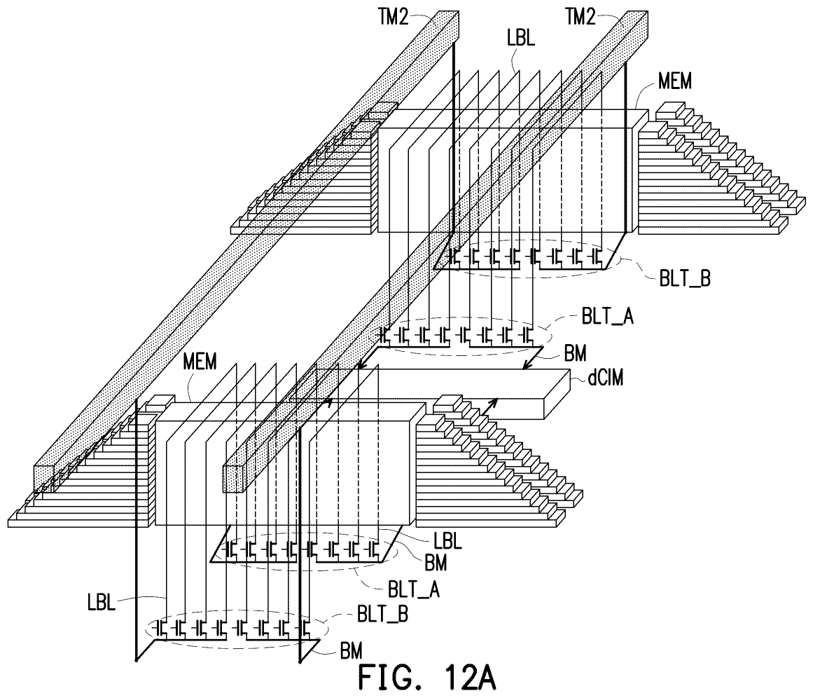

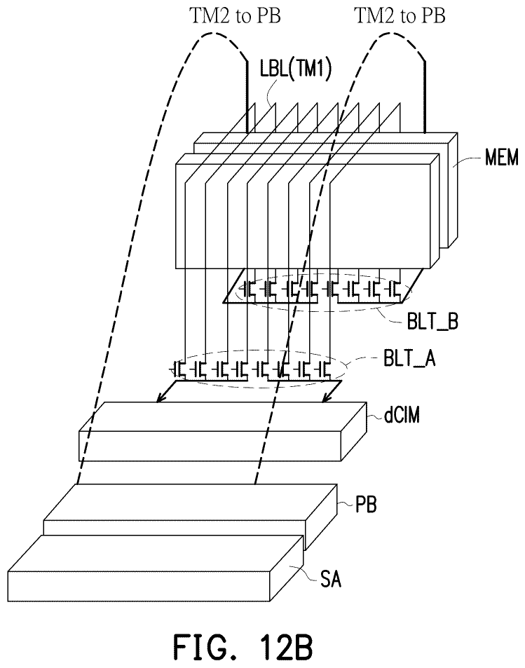

FIGS. 12A and 12B are schematic diagrams showing an entire 3D memory device having a digital computing in memory function according to at least one embodiment of the disclosure. In addition, FIG. 12B is an enlarged part of FIG. 12A. FIG. 2 mainly describes the architecture of the digital CIM circuit, but does not show the components (e.g., sense amplifiers) required for general operations such as programming, erasing, and reading of the memory array 110. As shown in FIG. 12A, a conceptual diagram of a general architecture of 3D memory is exemplified. A 3D memory device includes multiple tiles MEM consisting of the memory array and the like shown in FIG. 2. Here, only the local bit line LBL (such as top metal layer TM1) is exemplified to facilitate the description. Two sets of bit line selection transistors BLT_A and BLT_B are disposed in the 3D memory device, wherein the bit line selection transistor BLT_A is equivalent to the bit line selection transistors BLT and BBLT shown in FIG. 2.

In addition, the bit line selection transistor BLT_A may be connected to the digital CIM circuit dCIM through a bottom metal layer BM. The digital CIM circuit dCIM includes the circuit including the latch 121a, the NOR gate 121b, and the adder tree 130 described in FIG. 2.

In addition, the other set of bit line selection transistors BLT_B is used for general operations such as programming, erasing, and reading of the 3D memory device. For example, during operation of the 3D memory device, a proper operating voltage may be applied to the local bit line LBL through the bit line selection transistor BLT_B. Generally, 3D memory devices may share a page buffer PB and a sense amplifier SA. During a read operation, the sense amplifier SA may sense the current when the memory cell is turned on so as to determine the data being read. For the general structure, the bit line selection transistor BLT_B may be connected to the page buffer PB through a top metal layer TM2 (as shown in FIG. 12B).

By providing two independent sets of bit line selection transistors BLT_A and BLT_B, the local bit line of the 3D memory device may be connected to the digital CIM circuit dCIM through the bit line selection transistor BLT_A so as to transmit the data (weight data) stored in the 3D memory device to the digital CIM circuit dCIM.

In addition, through the bit line selection transistor BLT_B, the 3D memory device is enabled to perform general operations, such as writing weight values into the 3D memory device, verifying the correctness of stored data, or erasing the data stored in the 3D memory device to rewrite the data.

The embodiment of the disclosure does not particularly limit the specific structure of the 3D memory device as long as there are two independent sets of bit line selection transistors BLT_A and BLT_B for dCIM and general memory operations.

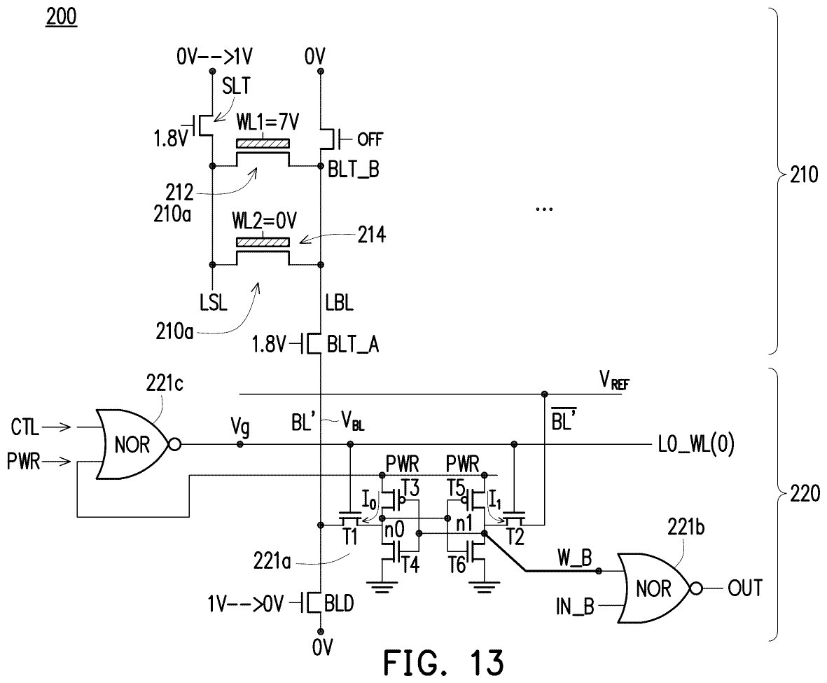

FIG. 13 is a schematic diagram showing a digital computing-in-memory circuit according to another embodiment of the disclosure. In the embodiment of FIG. 2, each latch 121a in the latch array 120 is woken up by the memory cell pair 112 in the memory array 110. In the embodiment of FIG. 13, each latch 221a of a latch array 220 is woken up by only one memory cell 212 for data transmission.

As shown in FIGS. 13 and 2, the configuration of a digital CIM circuit 200 in this embodiment is basically similar to the architecture of the digital CIM circuit 100 shown in FIG. 2, with the differences being only in the structure of a memory string 214, the latch, and relevant control schemes thereof. Furthermore, to facilitate the description, the circuit diagram shown in FIG. 13 is only a part of the digital CIM circuit 200. References may be made to FIG. 2 to construct the remaining parts. For example, a memory array 210 may include multiple stacked structures 210a (e.g., the stacked structures 110a and 110b in FIG. 2), and each of the stacked structures 210a may include multiple memory strings 214 (e.g., the memory strings 114 in FIG. 2). In addition, only one latch 221a in the latch array 220 is exemplified in FIG. 13. However, each latch 221a in the latch array 220 may be constructed under the same configuration as the latch array 120 in FIG. 2.

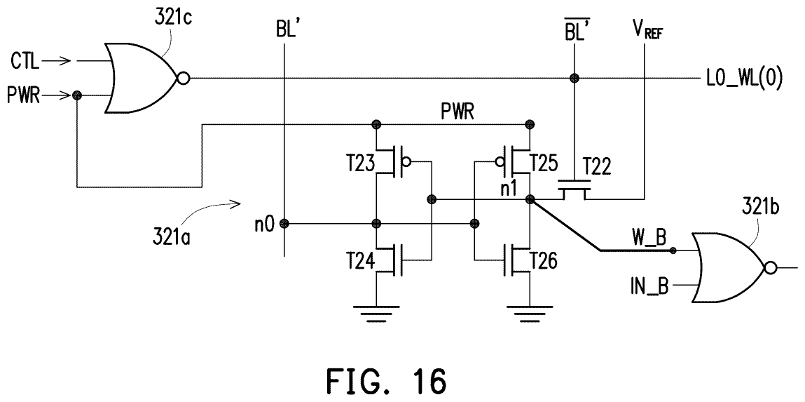

In addition, in FIG. 2, each latch 121a is woken up by the memory cell pair 112 (which may be referred to as a two-side bit line configuration), whereas the latch 221a in FIG. 16 is woken up by only one memory cell 212 (which may be referred to as a one-side bit line configuration). In this example, the memory array 210 may also be a 3D NOR flash memory array. In each memory string 214 of each stacked structure 210a, the memory cell 212 is used as a storage unit. Conversely, in FIG. 2, the memory cell pair 112 (i.e., including two memory cells 112a and 112b) serves as a storage unit in each memory string 114 of each of the stacked structures 110a and 110b in FIG. 2. In addition, the memory cell 212 may be programmed to a low threshold voltage state or a high threshold voltage state.

The latch 221a shown in FIG. 13 is basically in the same configuration as the latch 121a shown in FIG. 3. The latch 221a also includes six (MOS) transistors T1 to T6, making the latch 221a equivalent to an SRAM. Therefore, connections of these transistors of the latch 221a are omitted. Only the differences are described. The labels and numerals used in FIG. 3 are also used for the description below.

As shown in FIG. 13, as the latch 221a is woken up by the memory cell 212 in this embodiment, only the bit line BL′ of the latch 221a is coupled to the local bit line LBL of the memory array 210 through a bit line selection transistor BLT_A. The complementary bit line B̅L̅′̅ of the latch 221a is coupled to a reference voltage V_{REF}. In addition, the reference voltage V_{REF} is adjustable.

In this case, if the reference voltage V_{REF} is 0.15V, the latch 221a may operate properly as long as the voltage of the bit line BL′ of the latch 221a reaches 0.3V.

In addition, a latch circuit 221 includes a logic circuit 221c. The logic circuit 221c has a first input end, a second input end, and an output end. The output end is coupled to a word line of the latch 221a. The first input end receives a control signal CTL, and the second input end is coupled to the power supply voltage PWR of the latch 221a. The logic circuit 221c may be a NOR gate, a NAND gate, an inverter, or other logic gates. This circuit ensures that if one of the word line L0_WL(0) and the power decoder (for the power supply voltage PWR) is turned on, the other one may be turned off at the same time. That is, the logic circuit 221c is designed to enable the power decode (for the power supply voltage PWR) to be turned off when the word line L0_WL(0) is turned on, or to enable the word line L0_WL(0) to be turned off when the power decode (for the power supply voltage PWR) is turned on. A truth table of the NOR gate serving as the logic circuit 221c is shown in Table 3 below.

TABLE 3

| | |
|---|---|
| Input | Output OUT |

| CTL | PWR | L0_WL(0) |
|---|---|---|
| 0 V | 0 V | 1 V |
| 0 V | 1 V | 0 V |

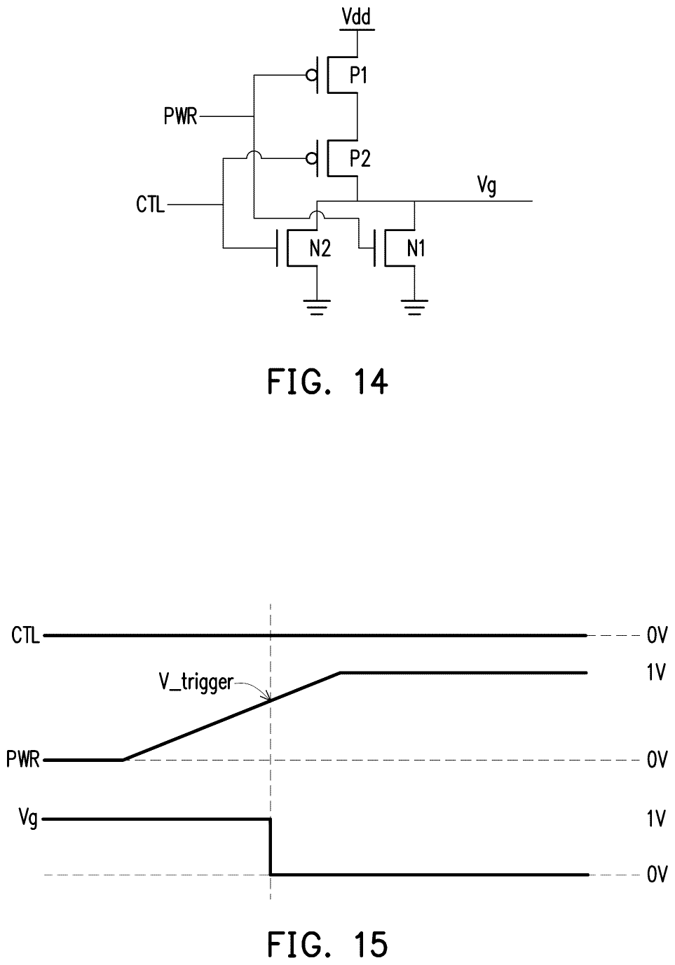

FIG. 14 illustrates an example of the logic circuit 221c. In this example, the logic circuit 221c may be implemented by a NOR gate. As shown in FIG. 14, the logic circuit 221c further comprises a first PMOS transistor P1, a second PMOS transistor P2, a first NMOS transistor N1 and a second NMOS transistor N2. The first PMOS transistor P1 has a control end, a first end, and a second end. The control end of the first PMOS transistor P1 is coupled to the power supply voltage PWR of the latch 221a and the first end of the first PMOS transistor P1 is coupled to a power source Vdd of the logic circuit 221c. The second PMOS transistor P2 has a control end, a first end, and a second end. The control end of the second PMOS transistor P2 is coupled to the control signal CTL, the first end of the second PMOS transistor P2 is coupled to the second end of the first PMOS transistor P1, and the second of the second PMOS transistor P2 is coupled to the output end of the logic circuit 221c.

In addition, the first NMOS transistor N1 has a control end, a first end, and a second end. The control end of the first NMOS transistor N1 is coupled to the power supply voltage PWR of the latch 221a, the first end of the first NMOS transistor N1 is coupled to the output end of the logic circuit 221c, and the second end of the first NMOS transistor N1 is coupled to the ground. Further, the second NMOS transistor N2 has a control end, a first end, and a second end. The control end of the second NMOS transistor N2 is coupled to the control signal CTRL, the first end of the second NMOS transistor N2 is coupled to the output end of the logic circuit 221c, and the second end of the second NMOS transistor N2 is coupled to the ground.

In addition, in a case that the logic circuit 221c is not implemented by the NOR gate, the circuit of the logic gate may be designed by another configuration. As shown in FIGS. 13 and 14, the output of the logic circuit 221c provides an output voltage Vg to the word line L0_WL(0) of the latch 221a. In this configuration, logic circuit 221c uses the analog power supply voltage PWR of the latch 221a as its input signal, rather than a digital input as its input signal. The transition of the output voltage Vg (i.e., the voltage of the word line L0_WL(0)) can be tuned by the power supply voltage PWR, i.e., the power decode.

FIG. 15 illustrates a timing diagram of the operation of the power decode of the logic circuit 221c. Referring to FIGS. 14 and 15, during the sensing operation, the control signal CTL is always at the low level (e.g., 0V). While sensing the memory cell 210a (refer to FIG. 13), the bit line voltage V_{BL} of the bit line BL′ and the reference voltage V_{REF} of the latch 221a are charged up. In addition, the power supply voltage PWR of the latch 221a is provided to the second input end of the NOR gate 221c. The power supply voltage PWR is ramped from a lower level (such as 0V) to a high level (such as 1V). At the beginning, the output voltage Vg is at the high level, the transistors T1, T2 are turned on. Therefore, during the ramp period of the power supply voltage PWR, the current I₀ and I₁ respectively flowing through the transistors T3, T5 will charge up the bit line voltage V_{BL} and the reference voltage V_{REF}. In such case, the power supply voltage PWR losses power to the bit line voltage V_{BL} and the reference voltage V_{REF}, and the loading of the power supply voltage PWR becomes high during the ramp period. Therefore, the ramp up speed becomes slow.

However, according to the embodiment, by coupling the power supply voltage PWR to the second input end of the logic circuit (such as NOR gate) 221c, the trigger point of the NOR gate can be tuned, so as to prevent the current I₀ and I₁ from charging up the bit line voltage V_{BL} and the reference voltage V_{REF}. According to the embodiment, as shown in FIG. 15, when the power supply voltage PWR is increased to the trigger voltage V_trigger, the output voltage Vg of the NOR gate 221c is transient, such as from the high level voltage (such as 1V) to the low level voltage (e.g., 0V). Then, the transistors T1, T2 are turned off, and accordingly, the current I₀ and I₁ twill no longer to flow through the to the transistors T1, T2 to charge up the bit line voltage V_{BL} and the reference voltage V_{REF}.

Therefore, according to the embodiment, the timing of the transition of the output voltage Vg of the logic circuit 221c can be tuned by the trigger voltage V_trigger during the ramp period of the power supply voltage PWR. In addition, the trigger voltage V_trigger may be further be tuned by trimming the sizes of the PMOS transistors and NMOS transistors that forms the logic circuit 221c. In this embodiment illustrated in FIG. 15, the trigger voltage V_trigger may be tuned by trimming the sizes of the first PMOS transistor P1, the second PMOS transistor P2 and the first (or second) NMOS transistor N1 (or N2).

In general, the trigger voltage V_trigger is considered as a division voltage of the power supply voltage PWR. Usually, the trigger voltage V_trigger may be determined by the internal resistances of the first PMOS transistor P1, the second PMOS transistor P2 and the first NMOS transistor N1. If the internal resistances of the first PMOS transistor P1, the second PMOS transistor P2 and the first NMOS transistor N1 are r1, r2 and r3 respectively, the trigger voltage V_trigger may be determined by following equation.

V_trigger=r3/(r1+r2+r3)

In addition, the internal resistance of the MOS transistor may be determined by the width of the MOS transistor. In this point of view, if the width of the first PMOS transistor P1, the second PMOS transistor P2 and the first NMOS transistor N1 are w1, w2 and w3 respectively, the trigger voltage V_trigger may be determined by following equation.

V_Trigger=w3/(w1+w2+w3)

In addition, the logic circuit 221c shown in FIG. 13 may be omitted, i.e., the latch 221a may be woken up without using the power decoding. That is, the power supply voltage PWR of the latch 221a is continuously supplied throughout the wake-up process. In addition, the circuit configuration for fixing the output of a NOR gate 221b shown in FIG. 6 may also be applied to the latch 221a shown in FIG. 13.

The above description is a method of waking up each latch 221a with a single memory cell. Thereafter, the weight data stored in the memory array 210 is written into each latch 221a. Thereafter, the digital CIM operation is performed. When digital CIM is performed under the architecture of FIG. 13, the main differences are only in the memory array 210 and the fact that the complementary bit line B̅L̅′̅ of the latch 221a is coupled to the reference voltage V_{REF}. Otherwise, the method of digital CIM is the same as the method illustrated in FIG. 5.

That is, after the weight data is written into each latch 221a, each bit line selection transistor BLT in the memory array 210 is turned off, making the latch array 220 independent of the memory array 210. Moreover, proper voltages are applied to all the word lines L0_WL(0) to LN_WL(N) in the latch array 220 to turn off (disable) all the word lines L0_WL(0) to LN_WL(N). Thereafter, each NOR gate 221b performs a multiplication operation based on the received weight signal W_B and the input signal IN_B input from an external source. Thereafter, the products are summed by the adder tree to output the MAC value.

FIG. 16 is a schematic diagram showing a variation of the latch according to another embodiment of the disclosure. The difference between a latch 321a shown in FIG. 16 and the latch 221a shown in FIG. 13 is that the latch 321a includes five transistors T22 to T26, i.e., the transistor T1 of the latch 221a is omitted. The latch 321a has the word line L0_WL(0), the bit line BL′, and the complementary bit line B̅L̅′̅.

As shown in FIG. 16, each of the transistors T22 to T26 has a control end (a gate), a first end (a first source/drain), and a second end (a second source/drain). The first end of the transistor T22 (a first transistor) is coupled to the reference voltage V_{REF}. The second end of the transistor T22 is coupled to the second node n1, and the control end of the transistor T22 is coupled to the complementary bit line B̅L̅′̅. The first end of the transistor T23 (a second transistor) is coupled to the power supply voltage PWR. The second end of the transistor T23 is coupled to the first node n0 and further to the bit line BL′, and the control end of the transistor T23 is coupled to the second node n1. The first end of the transistor T24 (a third transistor) is coupled to the first node n0. The second end of the transistor T24 is grounded, and the control end of the transistor T24 is coupled to the second node n1. The first end of the transistor T25 (a fourth transistor) is coupled to the power supply voltage PWR. The second end of the transistor T25 is coupled to the second node n1, and the control end of the transistor T25 is coupled to the first node n0. The first end of the transistor T26 (a fifth transistor) is coupled to the second node n1. The second end of the transistor T26 is coupled to a ground, and the control end of the transistor T26 is coupled to the first node n0. Similarly, the latch 321a consisting of the five transistors T22 to T26 is also equivalent to an SRAM.

In addition, an input end of a NOR gate 321b is coupled to the node n1 to receive the weight signal W_B from the memory array. Similarly, another input end of the NOR gate 321b receives the external input signal IN_B. Through the NOR gate 321b, a multiplication operation is performed on the weight signal W_B and the input signal IN_B.

In the configuration, the transistor T1 (the pass gate) on the side with the node n0 is omitted, and the node n0 is directly connected to the bit line BL′. This way, the latch 321a includes only five transistors, which makes the circuit simpler and better meets the operation requirements of digital CIM circuits.

In addition, the latch 321a may be applied to the memory array 210 shown in FIG. 13, that is, the latch 321a is suitable for being woken up by the single memory cell 212 so as to write the weight data into the latch 321a. In addition, with respect to the latch array consisting of the latches 321a, references may be made to the description of FIG. 2 for the configuration method of each latch 321a. For the configuration method of each latch 321a and the memory array, references may be made to the description of FIG. 13.

In addition, same as the description of FIG. 13, a logic circuit 321c shown in FIG. 16 may be omitted, i.e., the latch 321a may be woken up without power decoding. That is, the power supply voltage PWR of the latch 321a is continuously supplied throughout the wake-up process. In addition, the circuit architecture for fixing the output of a NOR gate 221b shown in FIG. 6 may also be applied to the latch 321a shown in FIG. 16.

In addition, the method of waking up the latch 321a in FIG. 16 and the method of digital CIM after writing the weight value (weight signal) into the latch 321a are the same as the methods in FIGS. 4 and 5. Thus, the methods may be adjusted by referring to the descriptions of FIGS. 4 and 5 and are not further described here.

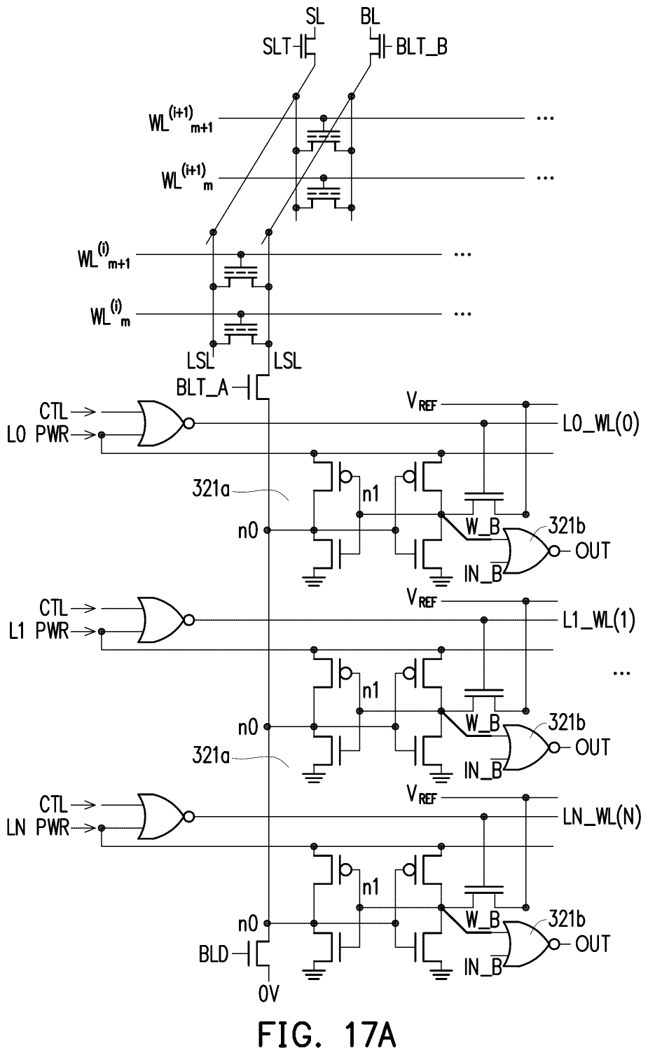

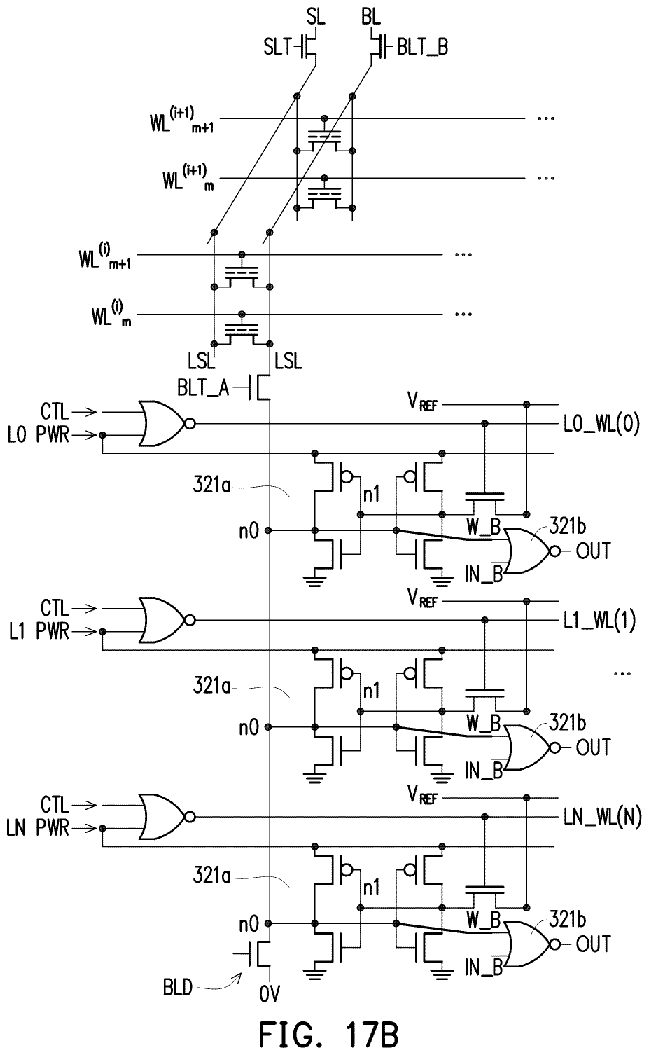

FIGS. 17A and 17B show 3D memory devices according to other variations of an embodiment of the disclosure. The 3D memory device in this variation uses the latch 321a shown in FIG. 16. In FIG. 17A, the input end of each NOR gate 321b for the weight signal W_B is coupled to the node n1 of the corresponding latch 321a. In FIG. 17B, the input end of each NOR gate 321b for the weight signal W_B is coupled to the node n0 of the corresponding latch 321a. The capacitive load may be adjusted through this method.

In summary, in the embodiment of the disclosure, a latch circuit, a NOR gate, and an adder tree are used to form a digital CIM circuit so as to perform digital CIM. During the data sensing phase, the latch may read weight information from a memory array. After the data is sensed, through a local bit line selection transistor located between the digital CIM circuit and the memory array, the digital CIM circuit may be independent of the memory array and perform calculation on a MAC value completely using a MOS circuit with lower power consumption. Thus, through the architecture in the embodiment of the disclosure, fast digital CIM may be achieved and energy consumption per bit may be reduced.

What is claimed is:

1. A computing in memory circuit, comprising:
a plurality of latches, each of the plurality of latches having a word line, a bit line, a complementary bit line, a first output end, and a second output end, wherein the bit line of each latch is coupled to a local bit line of a corresponding memory string among a plurality of memory strings in a memory array, and the complementary bit line of each latch is coupled to a local complementary bit line of the corresponding memory string in the memory array, wherein the corresponding memory string comprises a plurality of storage units, each of the storage units includes a memory cell pair, wherein the second output end provides a weight signal, sensed by the latch, from the memory cell pair; and
a plurality of NOR gates, each of the plurality of NOR gates having a first input end, a second input end, and an output end, wherein the first input end of each NOR gate is coupled to the second output end of a corresponding latch among the plurality of latches, the second input end of each NOR gate receives an external input signal, and the output end of each NOR gate outputs a product of the weight signal and the input signal.

2. The computing in memory circuit according to claim 1, wherein each latch further comprises:
a first transistor, having a control end, a first end, and a second end, wherein the control end is coupled to the word line, the first end is coupled to the bit line, and the second end is coupled to a first node serving as the first output end;
a second transistor, having a control end, a first end, and a second end, wherein the control end is coupled to the word line, the first end is coupled to the complementary bit line, and the second end is coupled to a second node serving as the second output end;
a third transistor, having a control end, a first end, and a second end, wherein the control end is coupled to the second node, the first end is coupled to a power supply voltage of the latch, and the second end is coupled to the first node;
a fourth transistor, having a control end, a first end, and a second end, wherein the control end is coupled to the second node, the first end is coupled to the first node, and the second end is coupled to a ground;
a fifth transistor, having a control end, a first end, and a second end, wherein the control end is coupled to the first node, the first end is coupled to the power supply voltage, and the second end is coupled to the second node; and
a sixth transistor, having a control end, a first end, and a second end, wherein the control end is coupled to the first node, the first end is coupled to the second node, and the second end is coupled to the ground,
wherein the third transistor and the fifth transistor are P-type transistors, and the first transistor, the second transistor, the fourth transistor, and the sixth transistor are N-type transistors.

3. The computing in memory circuit according to claim 1 further comprising:
an adder tree, receiving the product output by the output end of each of the plurality of NOR gates and summing the plurality of products output by the plurality of NOR gates so as to output a multiply-and-accumulate value,
wherein after each latch senses the weight signal stored in the memory array, the word line of each of the plurality of latches is disabled.

4. The computing in memory circuit according to claim 1, wherein when the memory array writes a data into the latch, the second input end of the NOR gate is set to a logic 1 so as to fix an output signal from the output end of the NOR gate.

5. The computing in memory circuit according to claim 1, wherein a power supply voltage for the latch is continuously supplied.

6. The computing in memory circuit according to claim 1, wherein a power supply voltage for the latch is only supplied when a data is written from the memory array to the latch.

7. The computing in memory circuit according to claim 1, wherein the memory cell pair comprises a first memory cell and a second memory cell, each of the first memory cell and the second memory cell having a control end, a first end, and a second end, wherein the control end of the first memory cell and the control end of the second memory cell are coupled to a same word line,
the first end of the first memory cell is coupled to a local source line, the second end is coupled to the local bit line, and
the first end of the second memory cell is coupled to a local complementary source line, and the second end is coupled to the local complementary bit line.

8. The computing in memory circuit according to claim 1, wherein the first memory cell is a low threshold voltage memory cell, and the second memory cell is a high threshold voltage memory cell.

9. The computing in memory circuit according to claim 7, wherein the memory array is a three-dimensional NOR flash memory array.

10. A computing in memory circuit, comprising:
a latch, having a word line, a bit line, a complementary bit line, a first output end, and a second output end; and
a first logic circuit, having a first input end, a second input end, and an output end, wherein the output end is coupled to the word line of the latch, the first input end receives a control signal, and the second input end is coupled to a power supply voltage of the latch,
wherein the complementary bit line of the latch is coupled to a reference voltage,
the power supply voltage is ramped up from a low level to a high level during an operation of the latch.

11. The computing in memory circuit according to claim 10, wherein a timing of a transition of an output signal of the first logic circuit is determined by a trigger voltage that is between the low level and the high level within a ramp period of the power supply voltage.

12. The computing in memory circuit according to claim 11, wherein in response to a voltage value of the power supply voltage reaches the trigger voltage, the output signal of the first logic circuit is transient.

13. The computing in memory circuit according to claim 10, the first logic circuit is a NOR gate.

14. The computing in memory circuit according to claim 13, wherein the first logic circuit further comprises:
a first PMOS transistor, having a control end, a first end, and a second end, wherein the control end of the first PMOS transistor is coupled to the power supply voltage and the first end of the first PMOS transistor is coupled to a power source of the first logic circuit;
a second PMOS transistor, having a control end, a first end, and a second end, wherein the control end of the second PMOS transistor is coupled to the control signal, the first end of the second PMOS transistor is coupled to the second end of the first PMOS transistor, and the second of the second PMOS transistor is coupled to the output end of the first logic circuit;
a first NMOS transistor, having a control end, a first end, and a second end, wherein the control end of the first NMOS transistor is coupled to the power supply voltage of the latch, the first end of the first NMOS transistor is coupled to the output end of the first logic circuit, and the second end of the first NMOS transistor is coupled to a ground; and
a second NMOS transistor, having a control end, a first end, and a second end, wherein the control end of the second NMOS transistor is coupled to the control signal, the first end of the second NMOS transistor is coupled to the output end of the first logic circuit, and the second end of the second NMOS transistor is coupled to the ground.

15. The computing in memory circuit according to claim 14, wherein the trigger voltage is determined by a ratio of a width of the first NMOS transistor with respect to a sum of a width of the first PMOS transistor, a width of the second PMOS transistor and the width of the first NMOS transistor.

16. The computing in memory circuit according to claim 10, wherein the latch further comprises:
a first transistor, having a control end, a first end, and a second end, wherein the control end is coupled to the word line, the first end is coupled to the bit line, and the second end is coupled to a first node serving as the first output end;
a second transistor, having a control end, a first end, and a second end, wherein the control end is coupled to the word line, the first end is coupled to the complementary bit line, and the second end is coupled to a second node serving as the second output end;
a third transistor, having a control end, a first end, and a second end, wherein the control end is coupled to the second node, the first end is coupled to the power supply voltage of the latch, and the second end is coupled to the first node;
a fourth transistor, having a control end, a first end, and a second end, wherein the control end is coupled to the second node, the first end is coupled to the first node, and the second end is coupled to a ground;
a fifth transistor, having a control end, a first end, and a second end, wherein the control end is coupled to the first node, the first end is coupled to the power supply voltage, and the second end is coupled to the second node; and
a sixth transistor, having a control end, a first end, and a second end, wherein the control end is coupled to the first node, the first end is coupled to the second node, and the second end is coupled to the ground,
wherein the third transistor and the fifth transistor are P-type transistors, and the first transistor, the second transistor, the fourth transistor, and the sixth transistor are N-type transistors.

17. The computing in memory circuit according to claim 10, wherein the latch further comprises:
a first transistor, having a control end, a first end, and a second end, wherein the first end is coupled to the reference voltage, the second end is coupled to a second node serving as the second output end, and the control end is coupled to the complementary bit line;
a second transistor, having a control end, a first end, and a second end, wherein the first end is coupled to the power supply voltage, the second end is coupled to a first node serving as the first output end, the second end further being coupled to the bit line, wherein the control end is coupled to the second node;
a third transistor, having a control end, a first end, and a second end, wherein the first end is coupled to the first node, the second end is grounded, and the control end is coupled to the second node;
a fourth transistor, having a control end, a first end, and a second end, wherein the first end is coupled to the power supply voltage, the second end is coupled to the second node, and the control end is coupled to the first node; and
a fifth transistor, having a control end, a first end, and a second end, wherein the first end is coupled to the second node, the second end is coupled to the ground, and the control end is coupled to the first node;
wherein the second transistor and the fourth transistor are P-type transistors, and the first transistor, the third transistor, and the fifth transistor are N-type transistors.

18. The computing in memory circuit according to claim 10, wherein the first logic circuit is a NAND gate or an inverter.

19. A computing-in-memory circuit, comprising:
a plurality of latches, each of the plurality of latches having a word line, a bit line, a complementary bit line, a first output end, and a second output end, wherein the bit line of each of the plurality of latches is coupled to a local bit line of a corresponding memory string among a plurality of memory strings in a memory array, wherein the corresponding memory string comprises a plurality of storage units, and each of the plurality of storage units consists of a single memory cell, wherein the second output end of each of the plurality of latches provides a weight signal, sensed by the latch, from the memory cell, and the complementary bit line of the latch is coupled to a reference voltage;
a plurality of first logic circuits, each of the plurality of first logic circuits having a first input end, a second input end, and an output end, wherein the output end of each of the plurality of first logic circuits is coupled to the word line of a corresponding latch among the plurality of latches, the first input end of each of the plurality of first logic circuits receives a control signal, and the second input end of each of the plurality of first logic circuits is coupled to a power supply voltage of the corresponding latch among the plurality of latches; and
a plurality of second logic circuits, each of the plurality of second logic circuits having a first input end, a second input end, and an output end, wherein the first input end of each of the plurality of second logic circuits is coupled to the second output end of the corresponding latch among the plurality of latches, the second input end of each of the plurality of second logic circuits receives an external input signal, and the output end of each of the plurality of second logic circuits outputs a product of the weight signal and the input signal.

20. The computing-in-memory circuit according to claim 19, further comprising:
an adder tree, receiving the product output by the output end of each of the plurality of second logic circuits and summing the plurality of products output by the plurality of second logic circuits so as to output a multiply-and-accumulate value,
wherein after each of the plurality of latches senses the weight signal stored in the memory array, the word line of each of the plurality of latches is disabled.

21. The computing in memory circuit according to claim 19, wherein the bit line of each of the plurality of latches is coupled to the local bit line of the corresponding memory string through a bit line selection transistor.

22. The computing-in-memory circuit according to claim 19, wherein when the memory array writes a data into the plurality of latches, the second input end of each of the plurality of second logic circuits is set to a logic 1 so as to fix an output signal from the output end of each of the plurality of second logic circuits.

23. The computing-in-memory circuit according to claim 19, wherein each of the plurality of latches further comprises:
a first transistor, having a control end, a first end, and a second end, wherein the control end is coupled to the word line, the first end is coupled to the bit line, and the second end is coupled to a first node serving as the first output end;
a second transistor, having a control end, a first end, and a second end, wherein the control end is coupled to the word line, the first end is coupled to the complementary bit line, and the second end is coupled to a second node serving as the second output end;
a third transistor, having a control end, a first end, and a second end, wherein the control end is coupled to the second node, the first end is coupled to the power supply voltage of the latch, and the second end is coupled to the first node;
a fourth transistor, having a control end, a first end, and a second end, wherein the control end is coupled to the second node, the first end is coupled to the first node, and the second end is coupled to a ground;
a fifth transistor, having a control end, a first end, and a second end, wherein the control end is coupled to the first node, the first end is coupled to the power supply voltage, and the second end is coupled to the second node; and
a sixth transistor, having a control end, a first end, and a second end, wherein the control end is coupled to the first node, the first end is coupled to the second node, and the second end is coupled to the ground,
wherein the third transistor and the fifth transistor are P-type transistors, and the first transistor, the second transistor, the fourth transistor, and the sixth transistor are N-type transistors.

24. The computing-in-memory circuit according to claim 19, wherein each of the plurality of latches further comprises:
a first transistor, having a control end, a first end, and a second end, wherein the first end is coupled to the reference voltage, the second end is coupled to a second node serving as the second output end, and the control end is coupled to the complementary bit line;
a second transistor, having a control end, a first end, and a second end, wherein the first end is coupled to the power supply voltage, the second end is coupled to a first node serving as the first output end, the second end further being coupled to the bit line, wherein the control end is coupled to the second node;
a third transistor, having a control end, a first end, and a second end, wherein the first end is coupled to the first node, the second end is grounded, and the control end is coupled to the second node;
a fourth transistor, having a control end, a first end, and a second end, wherein the first end is coupled to the power supply voltage, the second end is coupled to the second node, and the control end is coupled to the first node; and
a fifth transistor, having a control end, a first end, and a second end, wherein the first end is coupled to the second node, the second end is coupled to the ground, and the control end is coupled to the first node;
wherein the second transistor and the fourth transistor are P-type transistors, and the first transistor, the third transistor, and the fifth transistor are N-type transistors.

25. The computing-in-memory circuit according to claim 19, wherein the power supply voltage is ramped up from a low level to a high level during an operation of the of the plurality of latches.

26. The computing-in-memory circuit according to claim 19, wherein a timing of a transition of an output signal of the first logic circuit is determined by a trigger voltage determined between the low level and the high level within a ramp period of the power supply voltage.

27. The computing-in-memory circuit according to claim 26 wherein in response to a voltage value of the power supply voltage reaches the trigger voltage, the output signal of the first logic circuit is transient.

28. The computing-in-memory circuit according to claim 19, wherein each of the first logic circuit is a NOR gate.

29. The computing-in-memory circuit according to claim 28, wherein the NOR gate further comprises:
a first PMOS transistor, having a control end, a first end, and a second end, wherein the control end of the first PMOS transistor is coupled to the power supply voltage and the first end of the first PMOS transistor is coupled to a power source of the first logic circuit;
a second PMOS transistor, having a control end, a first end, and a second end, wherein the control end of the second PMOS transistor is coupled to the control signal, the first end of the second PMOS transistor is coupled to the second end of the first PMOS transistor, and the second of the second PMOS transistor is coupled to the output end of the first logic circuit;
a first NMOS transistor, having a control end, a first end, and a second end, wherein the control end of the first NMOS transistor is coupled to the power supply voltage of the latch, the first end of the first NMOS transistor is coupled to the output end of the first logic circuit, and the second end of the first NMOS transistor is coupled to a ground; and
a second NMOS transistor, having a control end, a first end, and a second end, wherein the control end of the second NMOS transistor is coupled to the control signal, the first end of the second NMOS transistor is coupled to the output end of the first logic circuit, and the second end of the second NMOS transistor is coupled to the ground.

30. The computing-in-memory circuit according to claim 29, wherein the trigger voltage is determined by a ratio of a width of the first NMOS transistor with respect to a sum of a width of the first PMOS transistor, a width of the second PMOS transistor and the width of the first NMOS transistor.

31. The computing-in-memory circuit according to claim 19, wherein each of the plurality of first logic circuits is a NAND gate or an inverter.

32. The computing-in-memory circuit according to claim 19, wherein each of the plurality of second logic circuits is a NOR gate.

33. The computing-in-memory circuit according to claim 19, wherein the single memory cell has a control end, a first end, and a second end, wherein the control end of the single memory cell is coupled to one of a plurality of word lines of the memory string, and
the first end of the single memory cell is coupled to a local source line, and the second end of the single memory cell is coupled to the local bit line.

34. The computing-in-memory circuit according to claim 33, wherein the memory array is a three-dimensional NOR flash memory array.
